(19) United States
(12) Patent Application Publication
(10) Pub. No.: US 2026/0206453 A1
(43) Pub. Date: Jul. 16, 2026

(54) DISPLAY DEVICE AND ELECTRONIC DEVICE COMPRISING THE SAME

(71) Applicant: Samsung Display Co., Ltd., Yongin-si (KR)

(72) Inventors: Kyung Bae KIM, Yongin-si (KR); Chan Keun KWON, Yongin-si (KR); Mun Gyu KIM, Yongin-si (KR); Dong Wan HA, Yongin-si (KR)

(21) Appl. No.: 19/340,024

(22) Filed: Sep. 25, 2025

(30) Foreign Application Priority Data
Jan. 14, 2025 (KR) 10-2025-0005535

(51) Int. Cl. H10K 59/35; H10K 59/121; H10K 59/80

(52) U.S. Cl. CPC H10K 59/353; H10K 59/1213; H10K 59/879

(57) ABSTRACT

A display device includes: a first substrate, a second substrate located on one side of the first substrate and coupled with the first substrate, a first pixel group located on a first surface of the first substrate, and a second pixel group located on a first surface of the second substrate, wherein the first substrate and the second substrate include different materials.

### CROSS-REFERENCE TO RELATED APPLICATION

This application claims priority to and the benefit of Korean Patent Application No. 10-2025-0005535, filed on Jan. 14, 2025, in the Korean Intellectual Property Office, the entire disclosure of which is incorporated by reference herein.

### BACKGROUND

### 1. Field

The present disclosure relates to a display device and an electronic device comprising the same.

### 2. Description of the Related Art

A head mounted display (HMD) is an image display device that is worn on a user's head in the form of glasses or helmets to form a focus at a close distance in front of the user's eyes. The head mounted display may implement virtual reality (VR) or augmented reality (AR).

The head mounted display magnifies an image displayed on a small display device by using a plurality of lenses, and displays the magnified image. Therefore, the display device applied to the head mounted display needs to provide high-resolution images, for example, images with a resolution of 3000 PPI (Pixels Per Inch) or higher. To this end, an organic light emitting diode on silicon (OLEDoS), which is a high-resolution small organic light emitting display device, is used as the display device applied to the head mounted display. The OLEDoS is an image display device in which an organic light emitting diode (OLED) is located on a semiconductor wafer substrate including complementary metal oxide semiconductor (CMOS).

### SUMMARY

Aspects and features of embodiments of the present disclosure provide a display device capable of providing high-resolution images.

Aspects and features of embodiments of the present disclosure also provide a head mounted display capable of providing high-resolution images.

However, aspects and features of embodiments of the present disclosure are not restricted to those set forth herein. The above and other aspects and features of embodiments of the present disclosure will become more apparent to one of ordinary skill in the art to which the present disclosure pertains by referencing the detailed description of the present disclosure given below.

According to one or more embodiments of the present disclosure, a display device includes: a first substrate, a second substrate located on one side of the first substrate and coupled with the first substrate, a first pixel group located on a first surface of the first substrate, and a second pixel group located on a first surface of the second substrate, wherein the first substrate and the second substrate include different materials.

According to one or more embodiments of the present disclosure, the first substrate is a single crystal semiconductor substrate, and the second substrate may be a glass substrate or a plastic substrate.

According to one or more embodiments of the present disclosure, the first substrate includes: a first sub-substrate including a first pixel circuit unit, and a second sub-substrate located on the first sub-substrate and including a second pixel circuit unit connected to the first pixel circuit unit, and a plurality of light emitting elements connected to the first pixel circuit unit.

According to one or more embodiments of the present disclosure, an area of the first sub-substrate may be smaller than an area of the second sub-substrate.

According to one or more embodiments of the present disclosure, the number per unit area of first pixels in the first pixel group may be different from the number per unit area of second pixels in the second pixel group.

According to one or more embodiments of the present disclosure, the display device further includes: a first driving circuit unit configured to drive the first pixel group, and a second driving circuit unit configured to drive the second pixel group, wherein the first driving circuit unit is located on the first surface of the first sub-substrate and connected to the first pixel group via a plurality of through holes.

According to one or more embodiments of the present disclosure, the display device further includes: a first driving circuit unit configured to drive the first pixel group, and a second driving circuit unit configured to drive the second pixel group, wherein the second substrate includes a main region and a sub-region extending from one side of the main region, the sub-region including a flexible material, and the second driving circuit unit is located in the sub-region and connected to the second pixel group.

According to one or more embodiments of the present disclosure, the sub-region includes a bending portion, and the second driving circuit unit is located on one side of the bending portion and located on a second surface of the second substrate.

According to one or more embodiments of the present disclosure, the second substrate includes a plurality of second substrates, and the plurality of second substrates is connected to the first substrate and surround the first substrate.

According to one or more embodiments of the present disclosure, the second substrate includes a main region and a sub-region extending from one side of the main region, the sub-region including a flexible material, and positions of the sub-regions on the plurality of second substrates may be all the same.

According to one or more embodiments of the present disclosure, a size of an emission area defined by each of a plurality of pixels in the first pixel group may be different from a size of an emission area defined by each of a plurality of pixels in the second pixel group.

According to one or more embodiments of the present disclosure, the display device further includes: a boundary portion located between the first substrate and the second substrate, a first lens group located on the first substrate, a second lens group located on the second substrate, and a third lens group located at the boundary portion.

According to one or more embodiments of the present disclosure, a direction in which light is refracted by the first lens group may be different from a direction in which light is refracted by the third lens group.

According to one or more embodiments of the present disclosure, a direction in which light is refracted by the second lens group may be different from a direction in which light is refracted by the third lens group.

According to one or more embodiments of the present disclosure, a refraction angle of light by the first lens group may be different from a refraction angle of light by the second lens group.

According to one or more embodiments of the present disclosure, the refraction angle of light by the first lens group may be less than the refraction angle of light by the second lens group, and a refraction angle of light by the third lens group may be less than the refraction angle of light by the first lens group.

According to one or more embodiments of the present disclosure, an electronic device includes: a processor configured to provide an image signal, a display module configured to receive the image signal from the processor and displaying an image, and a power module configured to supply power to the display module, wherein the display module includes: a first substrate, a second substrate located on one side of the first substrate and coupled with the first substrate, a first pixel group located on a first surface of the first substrate, and a second pixel group located on a first surface of the second substrate, wherein the first substrate and the second substrate include different materials.

According to one or more embodiments of the present disclosure, the first substrate is a single crystal semiconductor substrate, and the second substrate may be a glass substrate or a plastic substrate.

According to one or more embodiments of the present disclosure, the first substrate includes: a first sub-substrate including a first pixel circuit unit, and a second sub-substrate located on the first sub-substrate and including a second pixel circuit unit connected to the first pixel circuit unit, and a plurality of light emitting elements connected to the first pixel circuit unit.

According to one or more embodiments of the present disclosure, the display module further includes: a boundary portion located between the first substrate and the second substrate, a first lens group located on the first substrate, a second lens group located on the second substrate, and a third lens group located at the boundary portion.

The present disclosure may provide a display device having a large number of pixels per unit area and a relatively low manufacturing cost. To this end, a plurality of substrates containing different materials are used, but the refractive index of the lens and/or the like may be adjusted to prevent the boundary portion between the substrates from being visually recognized by an observer. Therefore, a display device having a low manufacturing cost and improved color reproducibility of an image may be provided.

### BRIEF DESCRIPTION OF THE DRAWINGS

The above and other aspects and features of the present disclosure will become more apparent by describing in detail example embodiments thereof with reference to the attached drawings, in which:

FIG. 1 is an exploded perspective view showing a display device according to one or more embodiments of the present disclosure;

FIG. 2 is a block diagram showing a display device according to one or more embodiments of the present disclosure;

FIG. 3 is an equivalent circuit diagram of a first sub-pixel according to one or more embodiments of the present disclosure;

FIG. 4 is a layout diagram illustrating an example of a display panel according to one or more embodiments of the present disclosure;

FIG. 5 is a block diagram showing components included in a display device according to one or more embodiments of the present disclosure;

FIG. 6 is a plan view showing a first surface of a display device according to one or more embodiments of the present disclosure;

FIG. 7 is a plan view showing a second surface of the display device according to one or more embodiments of the present disclosure;

FIG. 8 is a cross-sectional view showing a display device according to one or more embodiments of the present disclosure;

FIGS. 9 and 10 are cross-sectional views showing a display device according to one or more embodiments of the present disclosure;

FIG. 11 is a cross-sectional view showing in detail the cross-section of the second panel portion according to one or more embodiments of the present disclosure;

FIG. 12 is a layout diagram showing an example of the display area of FIG. 4;

FIG. 13 is a layout diagram showing another example of the display area of FIG. 4;

FIG. 14 is a plan view showing a driver of a first panel portion according to one or more embodiments of the present disclosure;

FIG. 15 is a plan view showing a display unit of a first panel portion according to one or more embodiments of the present disclosure;

FIG. 16 is a pixel circuit diagram according to one or more embodiments of the present disclosure;

FIG. 17 is a drawing showing wires located in a driver of a first panel portion according to one or more embodiments of the present disclosure;

FIG. 18 is a drawing showing connection between a pixel circuit and wires located in a display unit of a first panel portion according to one or more embodiments of the present disclosure;

FIG. 19 is a schematic cross-sectional view of a first panel portion according to one or more embodiments of the present disclosure;

FIG. 20 is a schematic view showing a rear surface of the first panel portion according to one or more embodiments of the present disclosure;

FIG. 21 is a schematic cross-sectional view of a driver of a first panel portion according to one or more embodiments of the present disclosure;

FIG. 22 is a plan view showing a pixel defining film, and first electrodes and emission areas of a plurality of sub-pixels located in a display area of a display unit of a first panel portion according to one or more embodiments of the present disclosure;

FIG. 23 is a plan view showing a pixel defining film, and first electrodes and emission areas of a plurality of sub-pixels located in a display area of a display unit of a first panel portion according to one or more embodiments;

FIG. 24 is a cross-sectional view showing a part of a display unit of a first panel portion according to one or more embodiments;

FIG. 25 is a perspective view illustrating a head mounted display according to one or more embodiments of the present disclosure;

FIG. 26 is an exploded perspective view illustrating an example of the head mounted display of FIG. 25;

FIG. 27 is a perspective view illustrating a head mounted display according to one or more embodiments of the present disclosure;

FIG. 28 is a block diagram of an electronic device according to one or more embodiments of the present disclosure; and

FIG. 29 is schematic diagrams of electronic devices according to one or more embodiments of the present disclosure.

### DETAILED DESCRIPTION

The aspects and features of embodiments disclosed herein, and methods of achieving them, will become apparent upon reference to the embodiments described in detail with accompanying drawings. However, the present disclosure is not limited to embodiments disclosed herein, but will be embodied in many different forms, and these embodiments are provided merely to make the present disclosure complete and to fully inform one of ordinary skill in the art to which the present disclosure belongs, and the present disclosure is defined by the scope of the claims and their equivalents.

References to an element or layer as being “on” another element or layer include both cases in which another layer or element is directly on top of or interposed between other elements. Throughout this specification, like reference numerals refer to like components. The shapes, sizes, proportions, angles, numbers, etc. disclosed in the drawings to illustrate embodiments are examples and are not intended to be limiting to those shown herein.

Although first, second, and/or the like are used to describe various components, the components are not limited by these terms. Thus, a first component referred to herein may also be a second component within the technical idea of the present disclosure.

Each of the features of the various embodiments disclosed herein may be combined or combinable with each other, in part or in whole, and may be technically interlocked and operated in a variety of ways, and each embodiment may be practiced independently of or in conjunction with one another.

Specific embodiments will be described below with reference to the accompanying drawings. Configurations that function substantially the same between embodiments are given the same drawing designation and repeated description is omitted.

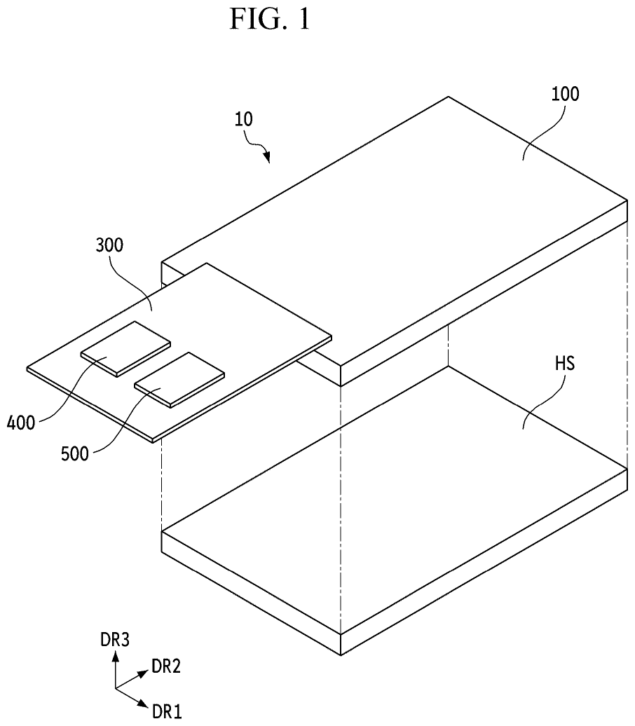

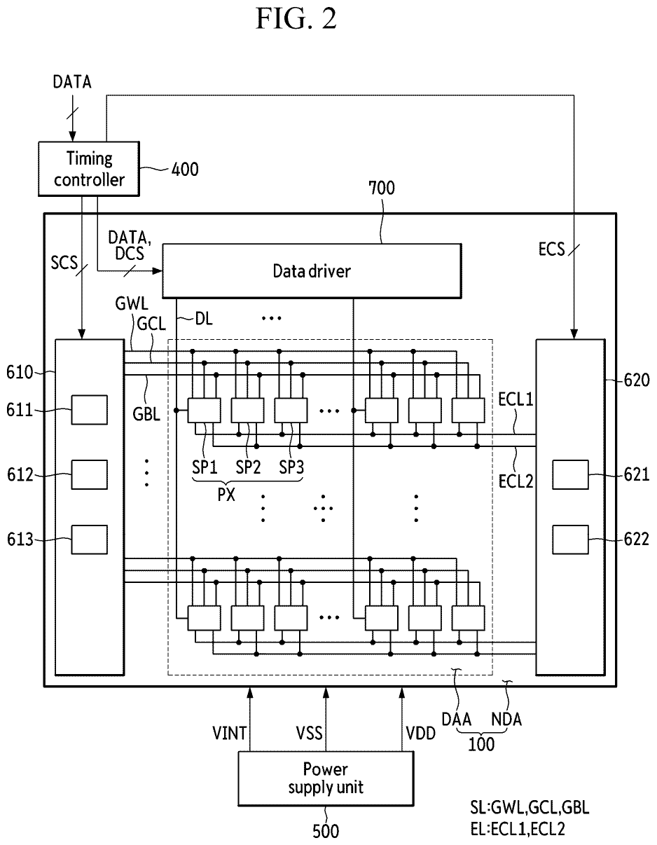

FIG. 1 is an exploded perspective view showing a display device according to one or more embodiments of the present disclosure. FIG. 2 is a block diagram showing a display device according to one or more embodiments of the present disclosure.

Referring to FIGS. 1 and 2, a display device 10 according to one or more embodiments is a device for displaying a moving image and/or a still image. The display device 10 according to one or more embodiments may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC), and/or the like. For example, the display device 10 according to one or more embodiments may be applied as a display unit of a television, a laptop, a monitor, a billboard, and/or an Internet-of-Things (IoT) terminal. Alternatively, the display device 10 according to one or more embodiments may be applied to a smart watch, a watch phone, a head mounted display (HMD) for implementing virtual reality and/or augmented reality, and/or the like.

The display device 10 according to one or more embodiments includes a display panel 100, a heat dissipation layer HS, a circuit board 300, a timing control circuit (e.g., a timing controller) 400, and a power supply unit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a selected curvature. The planar shape of the display panel 100 is not limited to a quadrilateral shape, and may be a shape similar to another polygonal shape, a circular shape, and/or an elliptical shape. The planar shape of the display device 10 may conform to the planar shape of the display panel 100, but the present disclosure is not limited thereto.

The display panel 100 includes a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA not displaying an image as shown in FIG. 2.

The plurality of pixels PX may be arranged in the display area DAA. The plurality of pixels PX may be arranged in a matrix form along the first direction DR1 and the second direction DR2. For example, the plurality of pixels PX may be arranged along rows and columns of a matrix form along the first direction DR1 and the second direction DR2. The plurality of scan lines SL and the plurality of emission control lines EL may extend in the first direction DR1, while being arranged along the second direction DR2. The plurality of data lines DL may extend in the second direction DR2, while being arranged along the first direction DR1.

The plurality of scan lines SL include a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

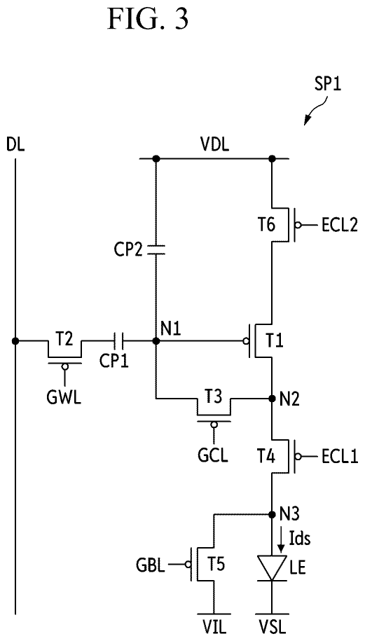

The plurality of pixels PX include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process and arranged on a semiconductor substrate. For example, the plurality of pixel transistors of the data driver 700 may be formed as complementary metal oxide semiconductor (CMOS) transistors, but the present disclosure is not limited thereto.

Each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL in response to a write scan signal of the write scan line GWL, and emit light from the light emitting element according to the data voltage.

The scan driver 610, the emission driver 620, and the data driver 700 may be located in the non-display area NDA.

The scan driver 610 includes a plurality of scan transistors, and the emission driver 620 includes a plurality of light emitting transistors. The plurality of scan transistors and the plurality of light emitting transistors may be formed on the semiconductor substrate through a semiconductor process. For example, the plurality of scan transistors and the plurality of light emitting transistors may be formed as CMOS transistors, but the present disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit (e.g., the timing controller) 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines ECL1. The second emission control driver 622 may generate second emission control signals according to the emission timing control signal ECS and sequentially output them to the second emission control lines ECL2.

The data driver 700 may include a plurality of data transistors, and the plurality of data transistors may be formed on the semiconductor substrate through a semiconductor process. For example, the plurality of data transistors may be formed as CMOS transistors, but the present disclosure is not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer HS may overlap the display panel 100 in a third direction DR3, which is a thickness direction of the display panel 100. The heat dissipation layer HS may be located on one surface, for example, the rear surface, of the display panel 100. The heat dissipation layer HS serves to dissipate heat generated from the display panel 100. The heat dissipation layer HS may include a metal layer having high thermal conductivity, such as graphite, silver (Ag), copper (Cu), and/or aluminum (Al).

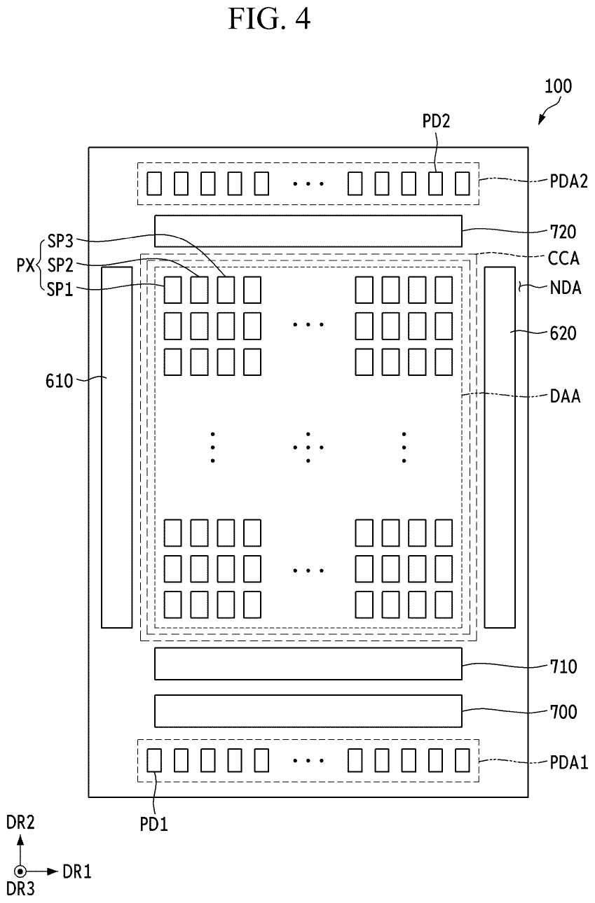

The circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board (FPCB) with a flexible material, and/or a flexible film. Although the circuit board 300 is illustrated in FIG. 1 as being unfolded, the circuit board 300 may be bent. In this case, one end of the circuit board 300 may be located on the rear surface of the display panel 100 and/or the rear surface of the heat dissipation layer HS. The other end of the circuit board 300 may be connected to the plurality of first pads PD1 (see FIG. 4) of the first pad portion PDA1 (see FIG. 4) of the display panel 100 by using a conductive adhesive member. One end of the circuit board 300 may be an opposite end of the other end of the circuit board 300.

The timing control circuit 400 may receive digital video data DATA and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data DATA and the data timing control signal DCS to the data driver 700.

The power supply unit 500 may generate a plurality of panel driving voltages by an external power voltage. For example, the power supply unit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply unit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply unit 500 may be supplied to the display panel 100 through the circuit board 300.

Alternatively, each of the timing control circuit 400 and the power supply unit 500 may be located in the non-display area NDA of the display panel 100, similarly to the scan driver 610, the emission driver 620, and the data driver 700. In this case, the timing control circuit 400 may include a plurality of timing transistors, and each power supply unit 500 may include a plurality of power transistors. The plurality of timing transistors and the plurality of power transistors may be formed on the semiconductor substrate through a semiconductor process. For example, the plurality of timing transistors and the plurality of power transistors may be formed as CMOS transistors, but the present disclosure is not limited thereto. Each of the timing control circuit 400 and the power supply unit 500 may be located between the data driver 700 and the first pad portion PDA1 (see FIG. 4).

FIG. 3 is an equivalent circuit diagram of a first sub-pixel according to one or more embodiments of the present disclosure.

Referring to FIG. 3, a first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

The first sub-pixel SP1 includes a plurality of transistors T1 to T6, a light emitting element LE, a first capacitor CP1, and a second capacitor CP2. The equivalent circuit diagram of the first sub-pixel SP1 may be applied to both a first panel portion and a second panel portion according to an embodiment to be described below.

The light emitting element LE emits light in response to a driving current Ids flowing through the channel of the first transistor T1. The emission amount of the light emitting element LE may be proportional to the driving current Ids. The first electrode of the light emitting element LE may be an anode electrode, and the second electrode of the light emitting element LE may be a cathode electrode. The light emitting element LE may be an organic light emitting diode (OLED) including a first electrode, a second electrode, and an organic light emitting layer located between the first electrode and the second electrode, but the present disclosure is not limited thereto. For example, the light emitting element LE may be an inorganic light emitting element including a first electrode, a second electrode, and an inorganic semiconductor located between the first electrode and the second electrode, in which case the light emitting element LE may be a micro light emitting diode.

The first transistor T1 may be a driving transistor that controls a source-drain current Ids (hereinafter referred to as “driving current”) flowing between the source electrode and the drain electrode according to a voltage applied to the gate electrode.

A second transistor T2 may be located between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be located between a first node N1 (e.g., a gate electrode of the first transistor T1) and a second node N2 (e.g., a drain electrode of the first transistor T1). The third transistor T3 is turned on by the write control signal of the write control line GCL to connect the first node N1 to the second node N2. For this reason, when the gate electrode and the drain electrode of the first transistor T1 are connected, the first transistor T1 may operate like a diode (e.g., the first transistor may be diode-connected).

The fourth transistor T4 may be connected between the second node N2 and a third node N3. The fourth transistor T4 is turned on by the first emission control signal of the first emission control line ECL1 to connect the second node N2 to the third node N3. Accordingly, the driving current of the first transistor T1 may be supplied to the light emitting element LE. A fifth transistor T5 may be located between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE.

The sixth transistor T6 may be located between the source electrode of the first transistor T1 and the second driving voltage line VDL. The sixth transistor T6 is turned on by the second emission control signal of the second emission control line ECL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is formed between the first node N1 and the drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (MOSFET). For example, each of the first to sixth transistors T1 to T6 may be a p-type MOSFET, but the present disclosure is not limited thereto. Each of the first to sixth transistors T1 to T6 may be an n-type MOSFET. Alternatively, some of the first to sixth transistors T1 to T6 may be p-type MOSFETs, and each of the remaining transistors may be an n-type MOSFET.

Although it is illustrated in FIG. 3 that the first sub-pixel SP1 includes six transistors T1 to T6 and two capacitors CP1 and CP2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the present disclosure.

FIG. 4 is a layout diagram illustrating an example of a display panel according to one or more embodiments of the present disclosure.

Referring to FIG. 4, the display area DAA of the display panel 100 according to one or more embodiments includes the plurality of pixels PX arranged in a matrix form. The non-display area NDA of the display panel 100 according to one or more embodiments includes the scan driver 610, the emission driver 620, the data driver 700, a first distribution circuit 710, a second distribution circuit 720, the first pad portion PDA1, and a second pad portion PDA2.

The scan driver 610 may be located on a first side of the display area DAA, and the emission driver 620 may be located on a second side of the display area DAA. For example, the scan driver 610 may be located on one side of the display area DAA in the first direction DR1, and the emission driver 620 may be located on the other side of the display area DAA in the first direction DR1. However, the present disclosure is not limited thereto, and the scan driver 610 and the emission driver 620 may be located on both the first side and the second side of the display area DAA.

The first pad portion PDA1 may include the plurality of first pads PD1 connected to pads or bumps of the circuit board 300 through a conductive adhesive member. The first pad portion PDA1 may be located on a third side of the display area DAA. For example, the first pad portion PDA1 may be located on one side of the display area DAA in the second direction DR2. The first pad portion PDA1 may be located outside the data driver 700 in the second direction DR2.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board (PCB) including a rigid material or a flexible printed circuit board (FPCB) including a flexible material.

The second pad portion PDA2 may be located on a fourth side of the display area DAA. For example, the second pad portion PDA2 may be located on the other side of the display area DAA in the second direction DR2. The second pad portion PDA2 may be located outside the second distribution circuit 720 in the second direction DR2.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be located on the third side of the display area DAA of the display panel 100. For example, the first distribution circuit 710 may be located on one side of the display area DAA in the second direction DR2.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be located on the fourth side of the display area DAA of the display panel 100. For example, the second distribution circuit 720 may be located on the other side of the display area DAA in the second direction DR2.

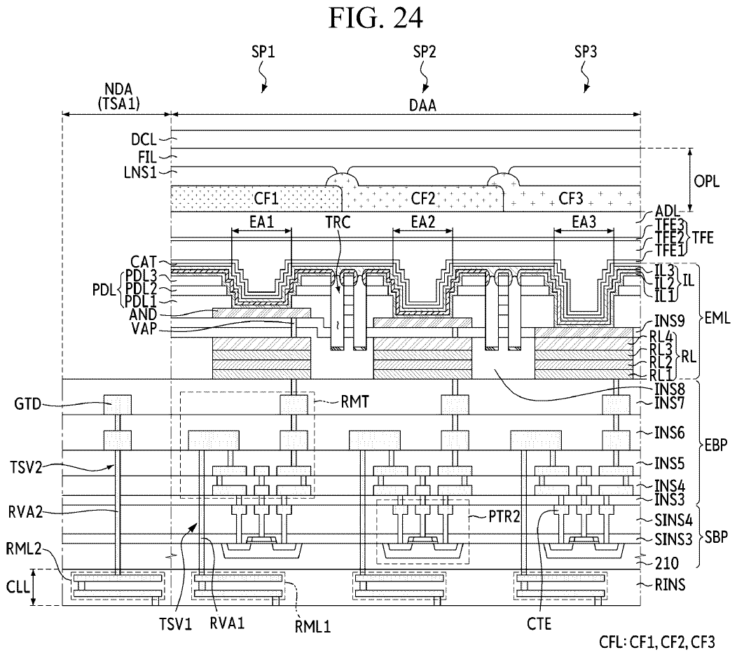

A cathode connection portion CCA may be a region in which a second electrode CAT (see FIG. 24) of a display element layer EML (see FIG. 24) is connected to the first driving voltage line VSL of the non-display area NDA. The cathode connection portion CCA may be located outside at least one side of the display area DAA. For example, the cathode connection portion CCA may be located outside at least on one side from among the left side, the right side, the upper side, and the lower side of the display area DAA. Alternatively, the cathode connection portion CCA may be located to be around (e.g., to surround) the display area DAA as shown in FIG. 4 in order to reduce or minimize a deviation in the first driving voltage VSS due to a voltage drop (IR drop) or voltage rise (IR rising) of the second electrode CAT in the display area DAA.

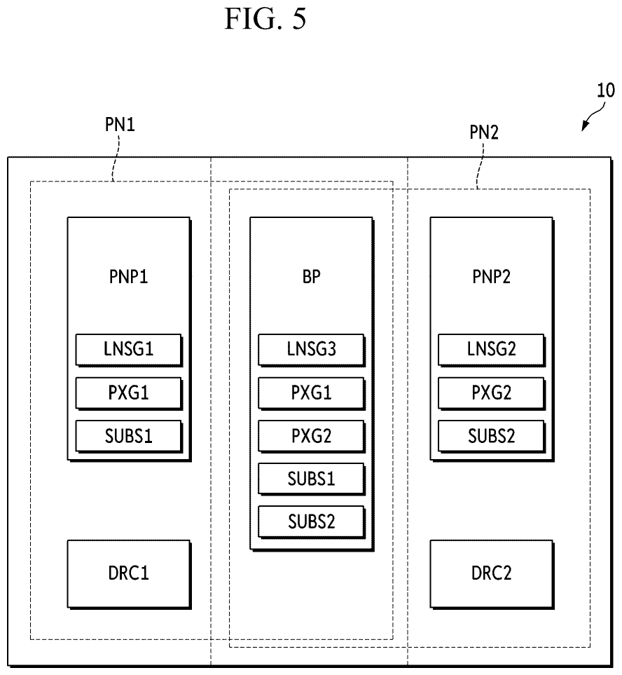

FIG. 5 is a block diagram showing components included in a display device according to one or more embodiments of the present disclosure.

Referring to FIG. 5, the display device 10 may include a first display panel PN1 and a second display panel PN2. The first display panel PN1 may include a first panel portion PNP1 and a first driving circuit unit DRC1, and the second display panel PN2 may include a second panel portion PNP2 and a second driving circuit unit DRC2. The display device 10 may further include a boundary portion BP located between the first panel portion PNP1 and the second panel portion PNP2. The boundary portion BP may be included in the first display panel PN1. The boundary portion BP may also be included in the second display panel PN2.

The first panel portion PNP1 may include a first substrate SUBS1, a first pixel group PXG1, and a first lens group LNSG1. The second panel portion PNP2 may include a second substrate SUBS2, a second pixel group PXG2, and a second lens group LNSG2. The first substrate SUBS1 and the second substrate SUBS2 may include different materials. The first pixel group PXG1 may include a plurality of first pixels. The first pixel may include a first sub-pixel, a second sub-pixel, and a third sub-pixel. The plurality of sub-pixels included in the first pixel may have a relatively small size. The first sub-pixel included in the first pixel may represent a first color, the second sub-pixel included in the first pixel may represent a second color, and the third sub-pixel included in the first pixel may represent a third color. The first color, the second color, and the third color may be any one color selected from the group consisting of red, green, and blue without overlapping each other. For example, the first color may be red, the second color may be green, and the third color may be blue, but the present disclosure is not limited thereto. The first pixel group PXG1 may be driven by the first driving circuit unit DRC1.

The second pixel group PXG2 may include a plurality of second pixels. The second pixel may include a first sub-pixel, a second sub-pixel, and a third sub-pixel. The plurality of sub-pixels included in the second pixel may have a relatively small size. The first sub-pixel included in the second pixel may represent a first color, the second sub-pixel included in the second pixel may represent a second color, and the third sub-pixel included in the second pixel may represent a third color. The first color, the second color, and the third color may be any one color selected from the group consisting of red, green, and blue without overlapping each other. For example, the first color may be red, the second color may be green, and the third color may be blue, but the present disclosure is not limited thereto. The second pixel group PXG2 may be driven by the second driving circuit unit DRC2.

The first display panel PN1 and the second display panel PN2 may be combined with each other. The display device 10 according to one or more embodiments may be implemented as a tiled display device. When the first display panel PN1 and the second display panel PN2 are combined, the boundary portion BP located between the first display panel PN1 and the second display panel PN2 may be formed. The boundary portion BP may include a boundary area formed at the edge of the first panel portion PNP1 and the edge of the second panel portion PNP2.

Because the boundary portion BP includes the boundary area formed at the edge of the first panel portion PNP1 and the edge of the second panel portion PNP2, the boundary portion BP may include the first substrate SUBS1 and the second substrate SUBS2. Because the boundary portion BP includes the boundary area formed at the edge of the first panel portion PNP1 and the edge of the second panel portion PNP2, the boundary portion BP may include the first pixel group PXG1 and the second pixel group PXG2.

The first panel portion PNP1 may include the first lens group LNSG1. The second panel portion PNP2 may include the second lens group LNSG2. The boundary portion BP may include a third lens group LNSG3. The first lens group LNSG1 may refract light emitted from the first pixel group PXG1. The second lens group LNSG2 may refract light emitted from the second pixel group PXG2. The third lens group LNSG3 may refract light emitted from the first pixel group PXG1 and the second pixel group PXG2 that are located at the boundary portion BP. The direction of light refracted by the third lens group LNSG3 may be different from the direction of light refracted by the first lens group LNSG1 and the direction of light refracted by the second lens group LNSG2.

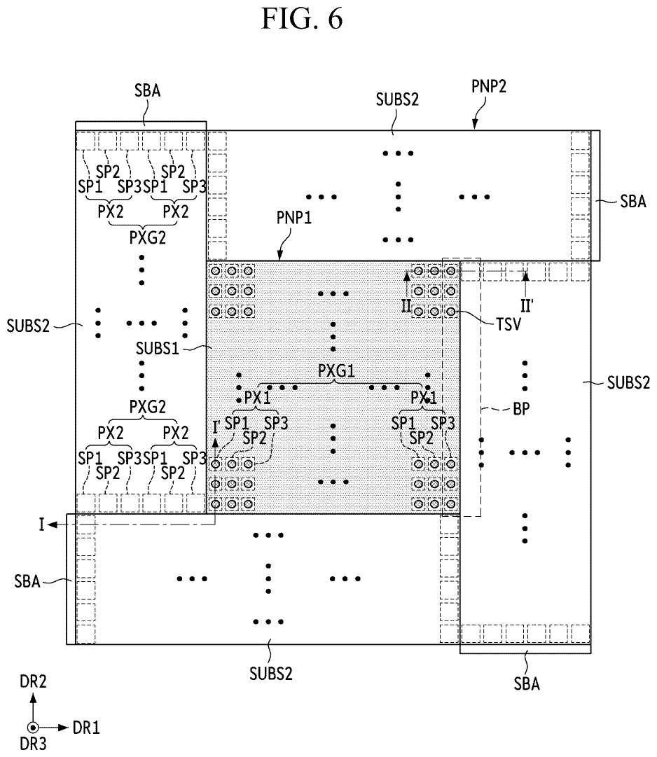

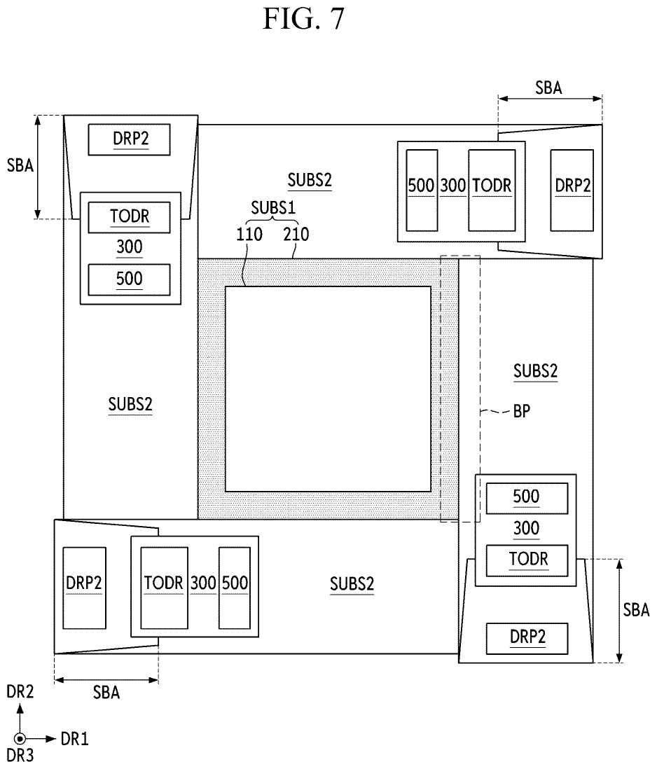

FIG. 6 is a plan view showing a first surface of the display device 10 according to one or more embodiments of the present disclosure. FIG. 7 is a plan view showing a second surface of the display device 10 according to one or more embodiments of the present disclosure.

Referring to FIGS. 6 and 7, the display device may include the first panel portion PNP1 and the second panel portion PNP2. A plurality of second panel portions PNP2 may be formed. The first panel portion PNP1 may be surrounded by the plurality of second panel portions PNP2, but the present disclosure is not limited thereto. The boundary portion BP may be formed between the first panel portion PNP1 and the second panel portion PNP2. The boundary portion BP may include a first pixel PX1 and a second pixel PX2.

The display device may include the first substrate SUBS1 and the second substrate SUBS2. A plurality of second substrates SUBS2 may be formed. The first substrate SUBS1 may be surrounded by the plurality of second substrates SUBS2, but the present disclosure is not limited thereto.

The first pixel group PXG1 located on a first surface (e.g., surface located in the third direction DR3) of the first panel portion PNP1 may include the plurality of first pixels PX1, and the first pixel PX1 may include the first sub-pixel SP1, the second sub-pixel SP2, and the third sub-pixel SP3. The plurality of sub-pixels SP1, SP2, and SP3 included in the first pixel PX1 may have a relatively small size.

The second pixel group PXG2 located on a first surface (e.g., surface located in the third direction DR3) of the second panel portion PNP2 may include the plurality of second pixels PX2, and the second pixel PX2 may include the first sub-pixel SP1, the second sub-pixel SP2, and the third sub-pixel SP3. The plurality of sub-pixels SP1, SP2, and SP3 included in the second pixel PX2 may have a relatively large size.

In one or more embodiments, the number per unit area of the first pixels PX1 included in the first pixel group PXG1 may be different from the number per unit area of the second pixels PX2 included in the second pixel group PXG2. For example, the number per unit area of the first pixels PX1 included in the first pixel group PXG1 may be greater than the number per unit area of the second pixels PX2 included in the second pixel group PXG2. Further, the resolution of the first substrate SUBS1 may be greater than the resolution of the second substrate SUBS2, but the present disclosure is not limited thereto. In the display device, the luminance per unit area of the first substrate SUBS1 may be the same as the luminance per unit area of the second substrate SUBS2.

The second substrate SUB2 may include a main region and a sub-region SBA. The sub-region may be located to extend from one side of the main region. In one or more embodiments, the positions of the sub-regions SBA on the second substrates SUBS2 may all be the same. Accordingly, the manufacturing cost may be reduced in the process of manufacturing the second panel portion PNP2 in which the positions of the sub-regions SBA are all the same.

In one or more embodiments, the first substrate SUBS1 and the second substrate SUBS2 may include different materials. For example, the first substrate SUBS1 may be a single crystal semiconductor substrate, and the second substrate SUBS2 may be a glass substrate and/or a plastic substrate.

The display device according to one or more embodiments of the present disclosure may include the first substrate SUBS1 and the second substrate SUBS2 including different materials, resulting in a reduced manufacturing cost. The manufacturing cost per unit area of the first substrate SUBS1 may be relatively greater than the manufacturing cost per unit area of the second substrate SUBS2. In this case, the manufacturing cost of forming at least a part of the display device with the first substrate SUBS1 and forming the other part thereof with the second substrate SUBS2 may be less than the manufacturing cost of forming the entire area of the display device with the first substrate SUBS1. Therefore, the display device according to one or more embodiments of the present disclosure may include both the first substrate SUBS1 that implements a relatively high resolution and the second substrate SUBS2 that implements a relatively low resolution in order to reduce the manufacturing cost.

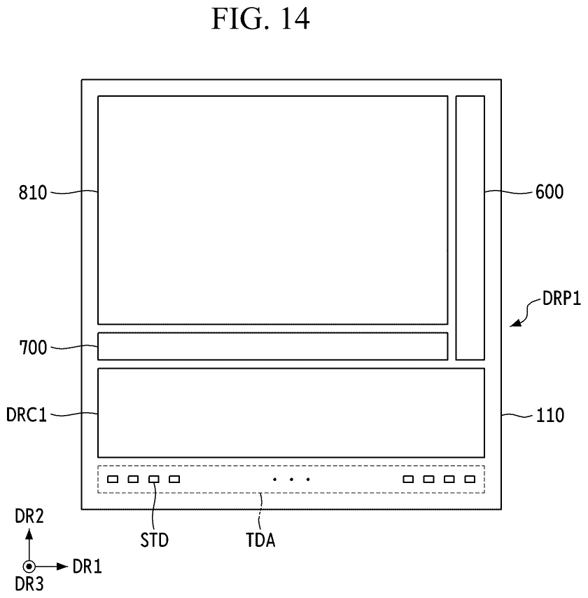

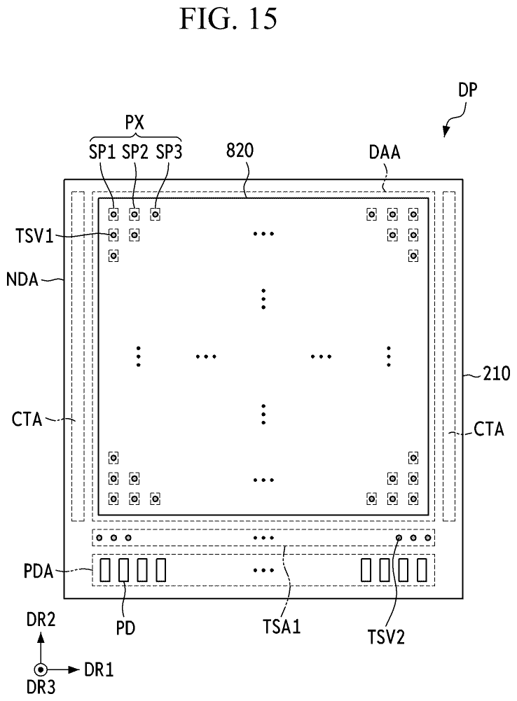

The first substrate SUBS1 of the first panel portion PNP1 may include a first sub-substrate 110 and a second sub-substrate 210. The first sub-substrate 110 may be located on the second surface (e.g., the surface located in a fourth direction DR4 opposite the third direction DR3) of the second sub-substrate 210. The second sub-substrate 210 may be greater than the first sub-substrate 110. The first pixel group PXG1 located on the first surface (e.g., the surface located in the third direction DR3) of the second sub-substrate 210 may include a plurality of light emitting elements. The light emitting elements of the first pixel group PXG1 may be driven by the first pixel circuit unit and the second pixel circuit unit. The first pixel circuit unit may be located on the first sub-substrate 110 and the second pixel circuit unit may be located on the second sub-substrate 210. The light emitting elements of the first pixel group PXG1 may be electrically connected to the first pixel circuit unit and the second pixel circuit unit connected to the first pixel circuit unit. The first driving circuit unit may be electrically connected to the plurality of light emitting elements included in the first pixel group PXG1 by a plurality of through holes TSV (e.g., TSV1, TSV2 of FIG. 15). The electrical connection relationship between the first pixel group PXG1 and the first driving circuit unit in the first panel portion PNP1 will be described in detail later with reference to FIG. 14 and subsequent drawings.

A second driver DRP2, the circuit board 300, a touch driver TODP, and the power supply unit 500 may be formed on second surfaces (e.g., surfaces located in the fourth direction DR4) of the plurality of second substrates SUBS2.

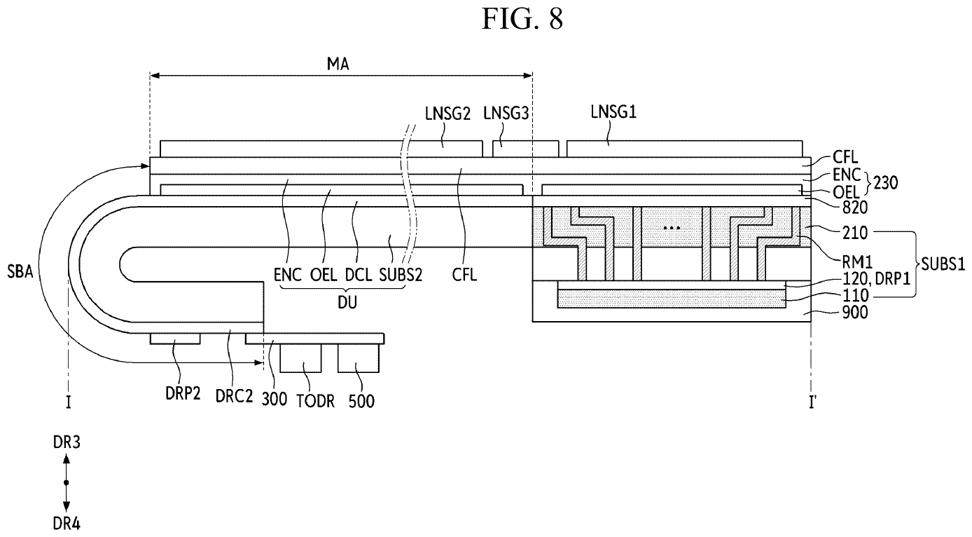

FIG. 8 is a cross-sectional view showing a display device according to one or more embodiments of the present disclosure. FIG. 8 is a cross-sectional view taken along the line I-I′ of FIG. 6.

Referring to FIG. 8, the second panel portion may include a color filter layer CFL, the second substrate SUBS2, a second driving circuit layer DCL, an optical element layer OEL, an encapsulation layer ENC, and the second lens group LNSG2.

At least a part of the second driving circuit layer DCL may be located on the first surface (e.g., surface located in the third direction DR3) of the second substrate SUBS2. The other part of the second driving circuit layer DCL may be located on the second surface (e.g., surface located in the fourth direction DR4) of the second substrate SUBS2. The second driving circuit layer DCL may include a plurality of transistors (e.g., thin film transistors) constituting the pixel circuit of pixels. The second driving circuit layer DCL may further include gate lines, data lines, power lines, gate control lines, fan-out lines that connect the second driver DRP2 to the data lines, and lead lines that connect the second driver DRP2 to the pad portion.

The optical element layer OEL may be located on the second driving circuit layer DCL. The optical element layer OEL may include a plurality of light emitting elements in which a pixel electrode (e.g., anode electrode), a light emitting layer, and a common electrode (e.g., cathode electrode) are sequentially stacked to emit light, and banks that define pixels. The plurality of light emitting elements of the optical element layer OEL may be arranged in the display area DA.

The light emitting layer may be an organic light emitting layer containing an organic material. The light emitting layer may include a hole transporting layer, an organic light emitting layer, and an electron transporting layer. When the pixel electrode receives a selected voltage through the transistor of the second driving circuit layer DCL and the common electrode receives the cathode voltage, holes and electrons may be transferred to the organic light emitting layer through the hole transporting layer and the electron transporting layer, respectively and may be combined with each other to emit light in the organic light emitting layer.

For another example, the plurality of light emitting elements may include a quantum dot light emitting diode including a quantum dot light emitting layer, an inorganic light emitting diode including an inorganic semiconductor, or a micro light emitting diode.

The encapsulation layer ENC may cover the top surface and the side surface of the optical element layer OEL, and may protect the optical element layer OEL. The encapsulation layer ENC may include at least one inorganic film and at least one organic film for encapsulating the optical element layer OEL.

The color filter layer CFL may be located on the encapsulation layer ENC. The color filter layer CFL may include a plurality of color filters respectively corresponding to the plurality of emission areas. Each of the color filters may selectively transmit light of a specific wavelength and may block or absorb light of a different wavelength. The color filter layer CFL may absorb a part of light coming from the outside of the display device to reduce reflected light due to external light. Accordingly, the color filter layer CFL may prevent color distortion caused by reflection of the external light.

Because the color filter layer CFL may be directly located on the encapsulation layer ENC, the display device may not require a separate substrate for the color filter layer CFL. Therefore, the thickness of the display device may be relatively reduced.

The sub-region SBA may extend from one side of a main region MA. The sub-region SBA may include a flexible material that can be bent, folded, and/or rolled. For example, when the sub-region SBA is bent, the sub-region SBA may overlap the main region MA in a thickness direction (the third direction DR3 or the fourth direction DR4). The sub-region SBA may include the second driver DRP2 and the pad portion electrically connected to the circuit board 300.

The first panel portion may include the color filter layer CFL, the first substrate SUBS1, a first driving circuit layer 120, the optical element layer OEL, the encapsulation layer ENC, and the first lens group LNSG1.

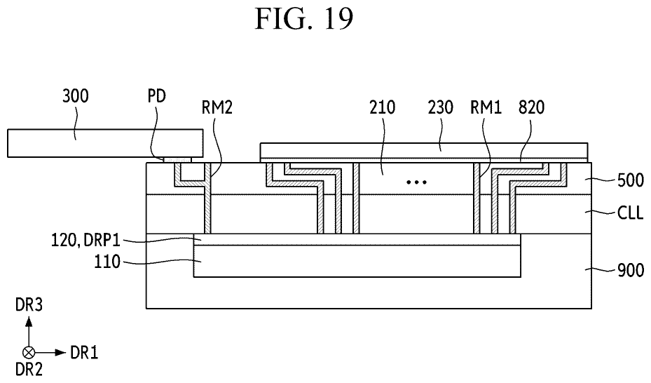

The first substrate SUBS1 may include a first sub-substrate 110 and a second sub-substrate 210. The second sub-substrate 210 may be located on the first sub-substrate 110. The first driving circuit layer 120 may be formed on the first sub-substrate 110. A first driver DRP1 may be formed in the first driving circuit layer 120. In the first driver DRP1 formed in the first driving circuit layer 120, a first pixel circuit unit, a first driving circuit unit, and/or the like may be located as will be described later (see FIG. 14). The description related to the cross-section of the first panel portion will be described in detail with reference to FIG. 19.

The thicknesses of the first substrate SUBS1 and the second substrate SUBS2 may be substantially the same. Specifically, the thickness of the second substrate SUBS2 including the sub-region SBA may be the same as the thickness of the second sub-substrate 210.

In one or more embodiments, the first lens group LNSG1 may be located on the first substrate SUBS1, and the second lens group LNSG2 may be located on the second substrate SUBS2. The third lens group LNSG3 may be located between the first lens group LNSG1 and the second lens group LNSG2. The third lens group LNSG3 may be located at the boundary portion located between the first substrate SUBS1 and the second substrate SUBS2.

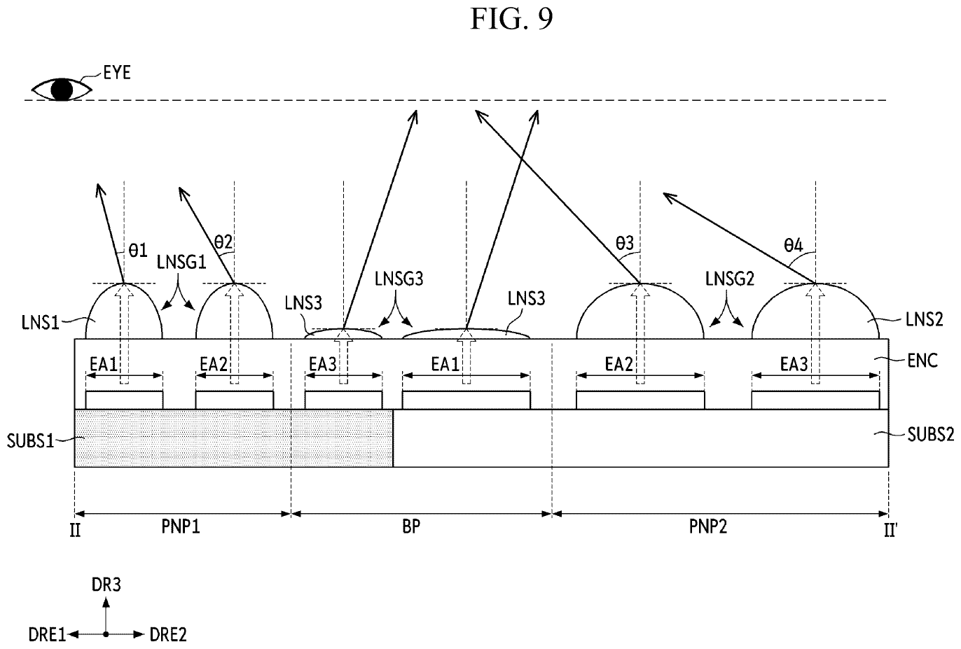

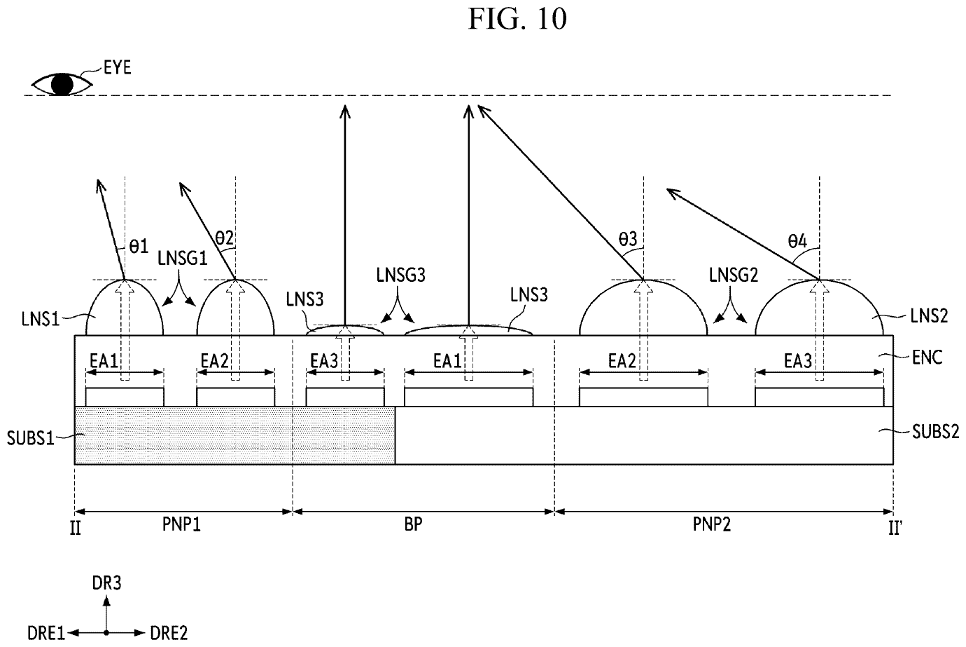

FIGS. 9 and 10 are cross-sectional views showing a display device according to one or more embodiments of the present disclosure. FIGS. 9 and 10 are also cross-sectional views taken along the line II-II′ of FIG. 6.

Referring to FIG. 9, in a display device according to one or more embodiments, the direction in which light emitted from the first panel portion PNP1 is refracted may be substantially the same as the direction in which light emitted from the second panel portion PNP2 is refracted. For example, light emitted from the first panel portion PNP1 may be refracted in a first refraction direction DRE1 where an eye EYE is located. Light emitted from the second panel portion PNP2 may also be refracted in the first refraction direction DRE1 where the eye EYE is located.

In one or more embodiments, the first lens group LNSG1 may refract light emitted from a first emission area EA1 and a second emission area EA2 on the first substrate SUBS1 in the first refraction direction DRE1. The second lens group LNSG2 may refract light emitted from the second emission area EA2 and a third emission area EA3 on the second substrate SUBS2 in the first refraction direction DRE1.

Light emitted from the first emission area EA1 on the first substrate SUBS1 may have a first refraction angle θ1 (with respect to the third direction DR3) and may be refracted in the first refraction direction DRE1. Light emitted from the second emission area EA2 on the first substrate SUBS1 may have a second refraction angle θ2 (with respect to the third direction DR3) and may be refracted in the first refraction direction DRE1. Light emitted from the second emission area EA2 on the second substrate SUBS2 may have a third refraction angle θ3 (with respect to the third direction DR3) and may be refracted in the first refraction direction DRE1, and light emitted from the third emission area EA3 on the second substrate SUBS2 may have a fourth refraction angle θ4 (with respect to the third direction DR3) and may be refracted in the first refraction direction DRE1.

In the case of considering the horizontal distance between the observer's eye EYE and the emission areas, the first refraction angle θ1 to the fourth refraction angle θ4 may all be different. The refraction angle of light by the first lens group LNSG1 may be different from the refraction angle of light by the second lens group LNSG2.

For example, the first refraction angle θ1 may be greater than the second refraction angle θ2, the second refraction angle θ2 may be greater than the third refraction angle θ3, and the third refraction angle θ3 may be greater than the fourth refraction angle θ4. For example, in one or more other embodiments, the first refraction angle θ1 may be less than the second refraction angle θ2, the second refraction angle θ2 may be less than the third refraction angle θ3, and the third refraction angle θ3 may be less than the fourth refraction angle θ4. However, the present disclosure is not limited thereto, and the magnitude relationship related to the refraction angle may be set in consideration of the horizontal distance and the vertical distance between the observer's eye EYE and the emission area.

The first emission area EA1, the second emission area EA2, and the third emission area EA3 on the first substrate SUBS1 may have a relatively small size than the first emission area EA1, the second emission area EA2, and the third emission area EA3 on the second substrate SUBS2. Therefore, the size of the plurality of first lenses LNS1 included in the first lens group LNSG1 may be smaller than the size of the plurality of second lenses LNS2 included in the second lens group LNSG2.

The boundary portion BP may include the third lens group LNSG3, and may be located between the first panel portion PNP1 and the second panel portion PNP2. The boundary portion BP may be included in the first display panel including the first panel portion PNP1 and may also be included in the second display panel including the second panel portion PNP2 (see FIG. 5).

The boundary portion BP may include both the first substrate SUBS1 and the second substrate SUBS2, and may include both the third emission area EA3 on the first substrate SUBS1 and the first emission area EA1 on the second substrate SUBS2. However, the present disclosure is not limited thereto. The emission areas may have different sizes on the first substrate SUBS1 and the second substrate SUBS2. The emission areas having relatively different sizes may be recognized by the eye EYE and cause unnaturalness on a screen or reduce image reproducibility. In a display device according to one or more embodiments of the present disclosure, the boundary portion BP where the third lens group LNSG3 is located may be defined between the first substrate SUBS1 and the second substrate SUBS2, and may prevent light emitted from the boundary portion BP from being refracted in a direction where the observer's eye EYE is located. Therefore, the present disclosure may provide a display device having a large number of pixels per unit area and a relatively low manufacturing cost. To this end, a plurality of substrates containing different materials are used, but the refractive index of the lens and/or the like may be adjusted to prevent the boundary portion between the substrates from being visually recognized by an observer. Therefore, a display device with improved color reproducibility of an image may be provided.

Accordingly, the third lens group LNSG3 may refract light emitted from the third emission area EA3 on the first substrate SUBS1 and the first emission area EA1 on the second substrate SUBS2 in a second refraction direction DRE2. The first refraction direction DRE1 and the second refraction direction DRE2 may be different. For example, the first refraction direction DRE1 may be a direction in which the observer's eye EYE is located, and the second refraction direction DRE2 may be a direction opposite to the direction in which the eye EYE is located, but the present disclosure is not limited thereto.

Referring to FIG. 10, in another embodiment, light may not be refracted by the third lens group LNSG3. Light emitted from the boundary portion BP to the third emission area EA3 on the first substrate SUBS1 and the first emission area EA1 on the second substrate SUBS2 may travel straight (in the third direction DR3) without being refracted by the third lens group LNSG3. In this case, the refraction angle of light by the third lens group LNSG3 located at the boundary portion BP may be substantially 0 degrees (with respect to the third direction DR3). Therefore, the first refraction angle θ1 and the second refraction angle θ2 may be less than the third refraction angle θ3 and the fourth refraction angle θ4, and the refraction angle of light by the third lens group LNSG3 may be less than the first refraction angle θ1 and the second refraction angle θ2.

Hereinafter, the components included in the second panel portion will be described in more detail.

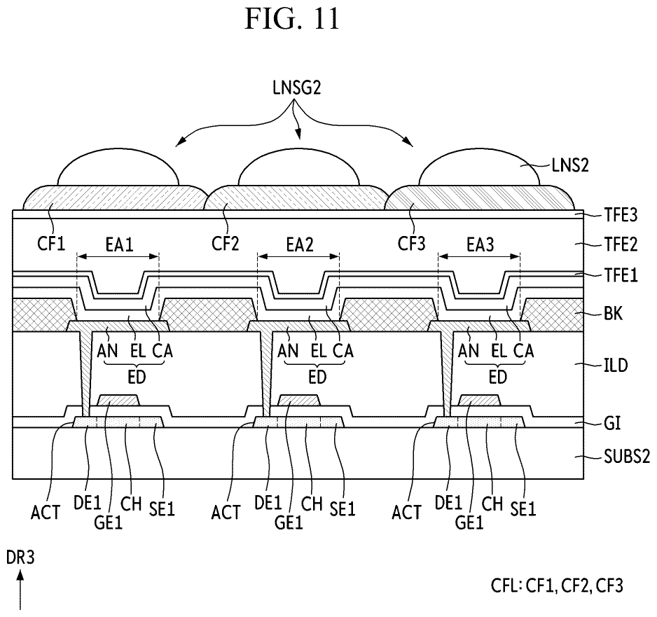

FIG. 11 is a cross-sectional view showing in detail the cross-section of the second panel portion according to one or more embodiments of the present disclosure.

Referring to FIG. 11, the display device according to one or more embodiments may include the second substrate SUBS2, a plurality of third transistors located on the second substrate SUBS2, one or more light emitting elements, and the second lens group LNSG2.

The second substrate SUBS2 may be a base substrate or a base member. The second substrate SUBS2 may include a flexible material which can be bent, folded, and/or rolled. For example, the second substrate SUBS2 may include a polymer resin such as polyimide (PI), but is not limited thereto. For another example, the second substrate SUBS2 may include a glass material, a plastic material, and/or a metal material.

The driving circuit layer may be located on the second substrate SUBS2. The driving circuit layer may include a plurality of third transistors and a second driving circuit unit. A plurality of transistors located on the second substrate SUBS2, included in the second driving circuit unit, or driven by the second driving circuit unit may be referred to as third transistors. The third transistor may be distinguished from the first transistor formed on a first single crystal semiconductor substrate and the second transistor formed on a second single crystal semiconductor substrate. The plurality of third transistors may be arranged on the second substrate SUBS2.

The driving circuit layer may include a plurality of active layers ACT, a gate insulating layer GI, a plurality of gate electrodes GE1, and at least one interlayer insulating layer ILD. In addition, the driving circuit layer may further include gate lines, data lines, power lines, gate control lines, fan-out lines, and lead lines that connect the second driver DRP2 to the pad portion.

The third transistor may include a first gate electrode GE1, a channel CH, a first source electrode SE1, and a first drain electrode DE1. The first gate electrode GE1 may be located on the gate insulating layer GI to overlap the active layer ACT in the third direction DR3. A region of the active layer ACT that overlaps the first gate electrode GE1 may be the channel CH. Regions of the active layer ACT that do not overlap the first gate electrode GE1 may be respectively the first source electrode SE1 and the first drain electrode DE1.

The gate insulating layer GI may be located on the second substrate SUBS2 covering the active layer ACT. The gate insulating layer GI may include at least one of tetraethylorthosilicate (TEOS), silicon nitride (SiNₓ), and/or silicon oxide (SiO₂). For example, the gate insulating layer GI may have a double film structure in which a silicon nitride film and/or a tetraethoxysilane film are sequentially stacked.

The plurality of gate electrodes GE1 may be located on the gate insulating layer GI. Each of the gate electrodes GE1 may include at least one of molybdenum (Mo), copper (Cu), aluminum, and/or titanium (Ti) and may be formed as a single layer or multiple layers. For example, the first gate electrode GE1 may include a triple film including a titanium film, an aluminum film, and a titanium film located sequentially on the gate insulating layer GI along the third direction DR3.

The interlayer insulating layer ILD may be located on the plurality of gate electrodes GE1 and the gate insulating layer GI. The interlayer insulating layer ILD may include an inorganic film, for example, a silicon nitride layer, a silicon oxynitride layer, a silicon oxide layer, a titanium oxide layer, and/or an aluminum oxide layer. The display device according to one or more embodiments may include the plurality of interlayer insulating layers ILD located between the gate insulating layer GI and the optical element layer.

The optical element layer may be located on the driving circuit layer. The optical element layer may include the bank BK (or pixel defining film), and the light emitting element ED.

The light emitting element ED may include an anode electrode AN, a light emitting stack EL, and a cathode electrode CA. The emission areas EA1, EA2, and EA3 may be regions in which the anode electrode AN, the light emitting stack EL, and the cathode electrode CA are sequentially stacked, and holes from the anode electrode AN and electrons from the cathode electrode CA are combined with each other in the light emitting stack EL to emit light.

In a top emission structure that emits light toward the cathode electrode CA with respect to the light emitting stack EL, the anode electrode (e.g., AN) may include a single layer of molybdenum (Mo), titanium (Ti), copper (Cu), and/or aluminum (Al), or may be formed to have a stacked structure (Ti/Al/Ti) of aluminum and titanium, a stacked structure (ITO/Al/ITO) of aluminum and ITO, an APC alloy, and/or a stacked structure (ITO/APC/ITO) of APC alloy and ITO to increase the reflectivity. The APC alloy is an alloy of silver (Ag), palladium (Pd), and copper (Cu).

The anode electrode AN may be located on the interlayer insulating layer ILD. The anode electrode AN may be connected to the first drain electrode DE1 through a contact hole penetrating the interlayer insulating layer ILD and the gate insulating layer GI.

The bank BK may define the emission areas EA1, EA2, and EA3. To this end, the bank BK may be located to expose a part of each anode electrode AN on the interlayer insulating layer ILD. The bank BK may cover the edge of each anode electrode AN. The bank BK may include an organic film such as acryl resin, epoxy resin, phenolic resin, polyamide resin, polyimide resin, and/and the like.

The light emitting stack EL may be located on the bank BK and the anode electrode AN. The light emitting stack EL may include a plurality of stack layers. For example, the light emitting stack EL may have a three-tandem structure including a first stack layer, a second stack layer, and a third stack layer that are sequentially stacked along the third direction DR3. However, the present disclosure is not limited thereto, and for example, the light emitting stack EL may have a two-tandem structure including two stack layers.

In the three-tandem structure described above, the light emitting stack EL may have a tandem structure including a plurality of stack layers that emit different lights. For example, the light emitting stack EL may include the first stack layer that emits light of the first color, the second stack layer that emits light of the second color, and the third stack layer that emits light of the third color. The first stack layer, the second stack layer, and the third stack layer may be sequentially stacked along the third direction DR3.

The first stack layer may have a structure in which a first hole transport layer, a first organic light emitting layer that emits light of the first color, and a first electron transport layer are sequentially stacked. The second stack layer may have a structure in which a second hole transport layer, a second organic light emitting layer that emits light of the second color, and a second electron transport layer are sequentially stacked. The third stack layer may have a structure in which a third hole transport layer, a third organic light emitting layer that emits light of the third color, and a third electron transport layer are sequentially stacked.

A first charge generation layer for supplying charges to the second stack layer and supplying electrons to the first stack layer may be located between the first stack layer and the second stack layer. The first charge generation layer may include an N-type charge generation layer that supplies electrons to the first stack layer and a P-type charge generation layer that supplies holes to the second stack layer. The N-type charge generation layer may include a dopant of a metal material.

A second charge generation layer for supplying charges to the third stack layer and for supplying electrons to the second stack layer may be located between the second stack layer and the third stack layer. The second charge generation layer may include an N-type charge generation layer that supplies electrons to the second stack layer and a P-type charge generation layer that supplies holes to the third stack layer.

The first color, second color, and third color described above may be different colors. For example, one of the first color, the second color, and the third color may be red, another color may be green, and the other color may be blue. The light emitting stack EL may provide light (e.g., white light) that is a mixture of light of the first color from the first organic light emitting layer, light of the second color from the second organic light emitting layer, and light of the third color from the third organic light emitting layer. Therefore, each of the light emitting elements ED may provide white light.

The cathode electrode CA may be located on the light emitting stack EL. The cathode electrode CA may be located to cover the light emitting stack EL. A capping layer may be further located on the cathode electrode CA.

In the top emission structure, the cathode electrode CA may include a transparent conductive material (TCO) such as ITO and/or IZO capable of transmitting light or a semi-transmissive conductive material such as magnesium (Mg), silver (Ag), or an alloy of magnesium (Mg) and silver (Ag). When the cathode electrode CA includes a semi-transmissive conductive material, the light output efficiency may be increased due to a micro-cavity effect.

The encapsulation layer ENC may be formed on the optical element layer. The encapsulation layer ENC may include at least one inorganic film TFE1 and TFE3 to prevent oxygen and/or moisture from permeating into the optical element layer. In addition, the encapsulation layer ENC may include at least one organic film to protect the optical element layer from foreign substances such as dust. For example, the encapsulation layer ENC may include a first encapsulation inorganic layer TFE1, an encapsulation organic layer TFE2, and a second encapsulation inorganic layer TFE3.

The first encapsulation inorganic layer TFE1 may be located on the cathode electrode CA, the encapsulation organic layer TFE2 may be located on the first encapsulation inorganic layer TFE1, and the second encapsulation inorganic layer TFE3 may be located on the encapsulation organic layer TFE2. The first encapsulation inorganic layer TFE1 and the second encapsulation inorganic layer TFE3 may be formed as multiple films in which one or more inorganic films of a silicon nitride layer, a silicon oxynitride layer, a silicon oxide layer, a titanium oxide layer, and an aluminum oxide layer are alternately stacked. The encapsulation organic layer TFE2 may be an organic film such as acryl resin, epoxy resin, phenolic resin, polyamide resin, polyimide resin, and/or the like.

The color filter layer CFL may be located on the encapsulation layer ENC. The color filter layer CFL may include a plurality of color filters CF.

The first color filter CF1 may overlap the first emission area EA1 of the first sub-pixel. Light of the first color (e.g., light of a red wavelength band) may pass through the first color filter CF1.

The second color filter CF2 may overlap the second emission area EA2 of the second sub-pixel. Light of the second color (e.g., light of a green wavelength band) may pass through the second color filter CF2.

The third color filter CF3 may overlap the third emission area EA3 of the third sub-pixel. Light of the third color (e.g., light of a blue wavelength band) may pass through the third color filter CF3.

The second lens group LNSG2 may be located on the color filter layer CFL. The second lens group LNSG2 may include the plurality of second lenses LNS2.

The second lenses LNS2 may respectively overlap the color filters CF1, CF2, and CF3. For example, the plurality of second lenses LNS2 may be located to respectively overlap the first color filter CF1, the second color filter CF2, and the third color filter CF3. Each of the second lenses LNS2 may have a convex parabolic shape along the third direction DR3.

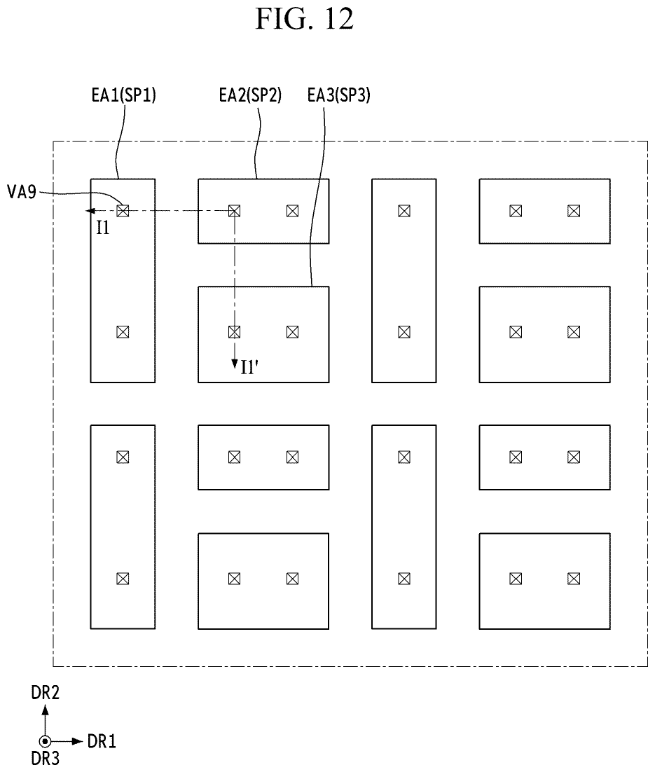

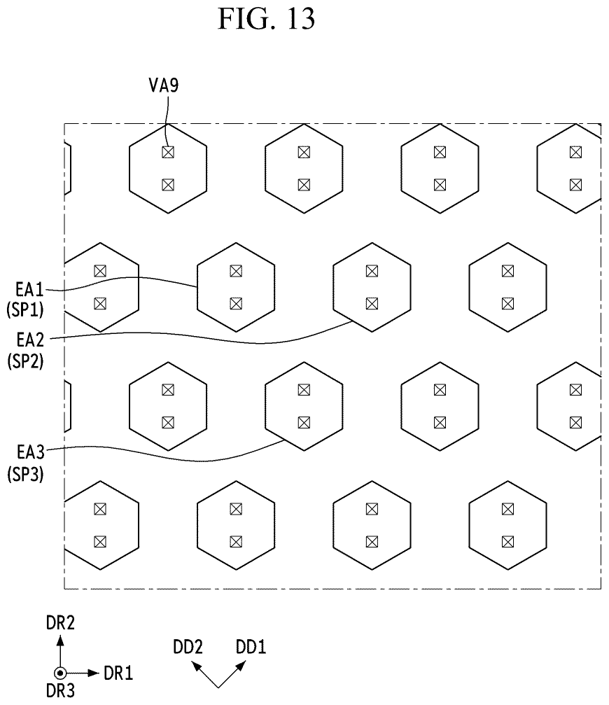

FIG. 12 is a layout diagram showing an example of the display area of FIG. 4. FIG. 13 is a layout diagram showing another example of the display area of FIG. 4.

Referring to FIGS. 12 and 13, each of the pixels PX includes a first emission area EA1 that is an emission area of the first sub-pixel SP1, a second emission area EA2 that is an emission area of the second sub-pixel SP2, and a third emission area EA3 that is an emission area of the third sub-pixel SP3.

The first emission area EA1, the second emission area EA2, and the third emission area EA3 may have, in a plan view, a quadrilateral or hexagonal shape as shown in FIGS. 12 and 13, but the present disclosure is not limited thereto. The first emission area EA1, the second emission area EA2, and the third emission area EA3 may have a polygonal shape other than a quadrangle or hexagon, a circular shape, an elliptical shape, or an atypical shape in a plan view.

As shown in FIG. 12, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

Alternatively, as shown in FIG. 13, the emission areas EA1, EA2, and EA3, may have a hexagonal shape in a plan view. In this case, the first emission area EA1 and the second emission area EA2 may be adjacent in the first direction DR1, the first emission area EA1 and the third emission area EA3 may be adjacent in a second diagonal direction DD2, and the second emission area EA2 and the third emission area EA3 may be adjacent in a first diagonal direction DD1. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. For example, the blue wavelength band may be a wavelength band of light whose main peak wavelength is in the range of approximately 370 nm to 460 nm, the green wavelength band may be a wavelength band of light whose main peak wavelength is in the range of approximately 480 nm to 560 nm, and the red wavelength band may be a wavelength band of light whose main peak wavelength is in the range of approximately 600 nm to 750 nm.

Each of the plurality of pixels PX may include three emission areas EA1, EA2, and EA3 as shown in FIG. 12, or may include four emission areas EA1, EA2, EA3, and EA4. In this case, the fourth emission area EA4 may emit the same second light as the second emission area EA2, but the present disclosure is not limited thereto.

The emission areas of the plurality of pixels PX may be arranged in a stripe structure in which the emission areas are arranged along the first direction DR1, a PENTILE® arrangement structure in which the emission areas EA1, EA2, and EA3 are arranged in a rhombus shape, or a hexagonal structure in which the emission areas each having a hexagonal shape are arranged as shown in FIG. 13. PENTILE® is a registered trademark of Samsung Display Co., Ltd., Republic of Korea.

Hereinafter, the components included in the first panel portion will be described in more detail.

FIG. 14 is a plan view showing a driver of a first panel portion according to one or more embodiments of the present disclosure. FIG. 15 is a plan view showing a display unit of a first panel portion according to one or more embodiments of the present disclosure.

Referring to FIGS. 14 and 15, the first driver DRP1 of the display device may include driving circuit elements of the display device. The first driver DRP1 may include a first single crystal semiconductor substrate 110 (or the first sub-substrate) and the first driving circuit unit DRC1, a gate driver 600, and a data driver 700 that are formed on the first single crystal semiconductor substrate 110. The gate driver 600 may include a scan driver.

The first driving circuit unit DRC1 may include a timing control circuit. In addition, the first driving circuit unit DRC1 may further include various circuits involved in driving of the display device, such as a gamma circuit and a logic circuit. The first driving circuit unit DRC1 may include driving circuit transistors formed on the first single crystal semiconductor substrate 110.

The first driving circuit unit DRC1 may receive digital video data and timing signals from the outside. The timing control circuit may generate a scan timing control signal and a data timing control signal for controlling the display unit DP in response to the timing signals. The timing control circuit may output the scan timing control signal to the gate driver 600. The timing control circuit may output the digital video data and the data timing control signal to the data driver 700.

The gate driver 600 may include a plurality of scan transistors formed on the first single crystal semiconductor substrate 110. The plurality of scan transistors may be formed through a semiconductor process. For example, the plurality of scan transistors may be formed as CMOS transistors. The gate driver 600 may receive the scan timing control signal from the first driving circuit unit DRC1. The scan driver of the gate driver 600 may generate scan signals according to the scan timing control signal of the first driving circuit unit DRC1 and output them sequentially to the scan lines.

The data driver 700 may receive the digital video data and the data timing control signal from the first driving circuit unit DRC1. The data driver 700 converts the digital video data into analog data voltages according to the data timing control signal and outputs the analog data voltages to data lines DL. In this case, the sub-pixels SP1, SP2, and SP3 are selected by the write scan signal of the gate driver 600, and data voltages may be supplied to the selected sub-pixels SP1, SP2, and SP3.

The first single crystal semiconductor substrate 110 may be a silicon substrate, a germanium substrate, or a silicon-germanium substrate. A plurality of first transistors may be formed on the first single crystal semiconductor substrate 110. The plurality of first transistors may be electrically connected to each other and constitute the first driving circuit unit DRC1, the gate driver 600, the data driver 700, and the first pixel circuit unit 810. The first transistors may be formed through a semiconductor process. For example, the plurality of transistors may be formed as complementary metal oxide semiconductor (CMOS) transistors.

The drawing illustrates that the first pixel circuit unit 810 is located on the upper side of the first driver DRP1, the data driver 700, the first driving circuit unit DRC1, and a signal terminal area TDA are located below the first pixel circuit unit 810, and the gate driver 600 is located on the left side of the first pixel circuit unit 810, which is one side of the first direction DR1. However, the present disclosure is not limited thereto. The position and inclusion relationship of the first driving circuit unit DRC1, the gate driver 600, and the data driver 700 of the first driver DRP1 may be variously modified according to the design structure of a plurality of circuit elements formed on the first single crystal semiconductor substrate 110.

The first pixel circuit unit 810 may include the plurality of first transistors, and a plurality of scan lines and data lines electrically connected to the first transistor. The first transistors may be electrically connected to the scan lines and the data lines, and may constitute a pixel circuit of each of sub-pixels SP1, SP2, and SP3.

In the signal terminal area TDA, a plurality of signal terminals STD arranged along the first direction DR1 may be located. The plurality of signal terminals STD may be electrically connected to the display unit DP and may be electrically connected to the circuit board 300 via them. The signal terminals STD may transmit an electrical signal applied from the circuit board 300 to the first driving circuit unit DRC1, the gate driver 600, and the data driver 700.

The display unit DP may include a second single crystal semiconductor substrate 210 (or, a second sub-substrate), and a plurality of pixels PX and the second pixel circuit unit 820 formed on the second single crystal semiconductor substrate 210. The display unit DP may include the display area DAA where the plurality of pixels PX are located and a non-display area NDA around (e.g., surrounding) the display area DAA. The display unit DP may include a first through hole area TSA1, a pad area PDA, and a common electrode contact area CTA that are located in the non-display area NDA. The common electrode contact area CTA may be located in the non-display area NDA on the left side and the right side of the display area DAA, which are opposite sides in the first direction DR1.

The second single crystal semiconductor substrate 210 may be a silicon substrate, a germanium substrate, or a silicon-germanium substrate. A plurality of second transistors may be formed in the second single crystal semiconductor substrate 210, and the plurality of second transistors may be electrically connected to each other to form a pixel circuit for light emission of the plurality of pixels PX. The second transistors may be formed through a semiconductor process. For example, the plurality of transistors may be formed as complementary metal oxide semiconductor (CMOS) transistors.

The plurality of pixels PX including light emitting elements may be located in the display area DAA. Each of the plurality of pixels PX may include three sub-pixels, for example, a first sub-pixel SP1, a second sub-pixel SP2, and a third sub-pixel SP3. Three sub-pixels SP1, SP2, and SP3 may constitute one pixel PX to display a color. However, the present disclosure is not limited thereto, and one pixel PX may include three or more sub-pixels. The plurality of sub-pixels SP may be arranged in a matrix form along the first direction DR1 and the second direction DR2. Each of the plurality of sub-pixels SP1, SP2, and SP3 may be electrically connected to the pixel circuit composed of the plurality of second transistors formed on the second single crystal semiconductor substrate 210. Each of the sub-pixels SP1, SP2, and SP3 may include light emitting elements, and the light emitting elements may emit light according to an electrical signal applied from a pixel circuit located in the display area DAA.

Some of the sub-pixels SP1, SP2, and SP3 located in the display area DAA of the display unit DP may overlap the first driver DRP1 in the thickness direction (e.g., the third direction DR3), and others may not overlap the first driver DRP1. The first driver DRP1 has a smaller area than that of the display unit DP and may be located adjacent to one side of the display unit DP. Accordingly, only some of the sub-pixels SP1, SP2, and SP3 may overlap the first driver DRP1 in the thickness direction (e.g., the third direction DR3).

The second pixel circuit unit 820 may include a plurality of second transistors formed on the second single crystal semiconductor substrate 210. The plurality of second transistors may be formed through a semiconductor process. For example, the plurality of second transistors may be formed as CMOS transistors. The second pixel circuit unit 820 may include a plurality of second transistors, and a driving voltage line electrically connected to the second transistors. The second transistor may be electrically connected to the first transistor of the first driver DRP1, the driving voltage lines VDL and VSL of the display unit DP, and the light emitting element, and may constitute the pixel circuit to which each of the sub-pixels SP1, SP2, and SP3 is connected.

According to one or more embodiments, the display unit DP of the display device may include a plurality of first through holes TSV1 that overlap the display area DAA. The first through holes TSV1 may be formed to penetrate the second single crystal semiconductor substrate 210 of the display unit DP. The first through holes TSV1 may form a connection path between the first pixel circuit unit 810 of the first driver DRP1 and the second pixel circuit unit 820 of the display unit DP. The plurality of first through holes TSV1 may be formed to respectively correspond to the sub-pixels SP1, SP2, and SP3 of the display unit DP. In one or more embodiments, the number of first through holes TSV1 may be equal to the number of sub-pixels SP1, SP2, and SP3, and the first through holes TSV1 may be formed to respectively overlap the subpixels SP1, SP2, and SP3. Alternatively, the number of first through holes TSV1 may be equal to the number of light emitting elements. However, the present disclosure is not limited thereto. The plurality of first through holes TSV1 may correspond to the respective sub-pixels SP1, SP2, and SP3, but may not necessarily be formed to overlap them. As will be described later, the plurality of sub-pixels SP1, SP2, and SP3 may be connected to the pixel circuit constituted by elements of the first pixel circuit unit 810 and the second pixel circuit unit 820 connected through the first through hole TSV1.

In the display device according to one or more embodiments, transistors included in the pixel circuit PXC and some of a plurality of wires connected to the transistors may be located on different single crystal semiconductor substrates. The display device may include the first driver DRP1 and the display unit DP, each including a different single crystal semiconductor substrate, and the transistors of the pixel circuit PXC and the plurality of wires may be dividedly located in the first driver DRP1 and the display unit DP. Because some wires and some circuit elements of the pixel circuit PXC are dividedly located on different single crystal semiconductor substrates, the display device may solve the difficulty of layout design due to high integration density in a small area, and may prevent the formation of parasitic capacitance between adjacent elements. Further, a voltage drop may be efficiently prevented by eliminating an unnecessary current path formed in the first driver DRP1 and the display unit DP. A more detailed description thereof will be given later with reference to other drawings.

The non-display area NDA may be located to be around (e.g., to surround) the display area DAA. The non-display area NDA may be an area where no pixels PX are located and therefore no light is emitted. The common electrode contact area CTA, the pad area PDA, and the plurality of first through hole areas TSA1 may be located in the non-display area NDA.

The common electrode contact area CTA may be located in the non-display area NDA on opposite sides of the display area DAA in the first direction DR1. For example, the common electrode contact area CTA may be located on the left side and the right side of the display area DAA. The common electrode contact area CTA may be an area in which the second electrode of the light emitting element located in each of the sub-pixels SP1, SP2, and SP3 of the display area DAA is electrically connected to the first driving voltage line VSL.

The first through hole area TSA1 may be located in the non-display area NDA on one side of the display area DAA in the second direction DR2. For example, the first through hole area TSA1 may be located on the lower side of the display area DAA and between the display area DAA and the pad area PDA. A plurality of second through holes TSV2 may be formed in the first through hole area TSA1. The second through holes TSV2 may be connection paths of signal connection wires that electrically connect the signal terminal STD of the first driver DRP1 to the circuit board 300. The plurality of second through holes TSV2 may be formed to respectively correspond to the signal terminals STD of the first driver DRP1. In one or more embodiments, the number of second through holes TSV2 may be equal to the number of signal terminals STD, and the second through holes TSV2 may be formed to respectively overlap the signal terminals STD. However, the present disclosure is not limited thereto. The circuit board 300 may be electrically connected to the signal terminal STD of the first driver DRP1 via the plurality of pads PD and the signal connection wire located in the second through hole TSV2.

The pad area PDA may be located on the lower side of the display area DAA, which is one side of the second direction DR2. The plurality of pads PD arranged along the first direction DR1 may be located in the pad area PDA. The circuit board 300 may be attached onto the plurality of pads PD. The pads PD may be electrically connected to the circuit board 300, and may serve to transmit the electrical signal applied from the circuit board 300 to the first driver DRP1.

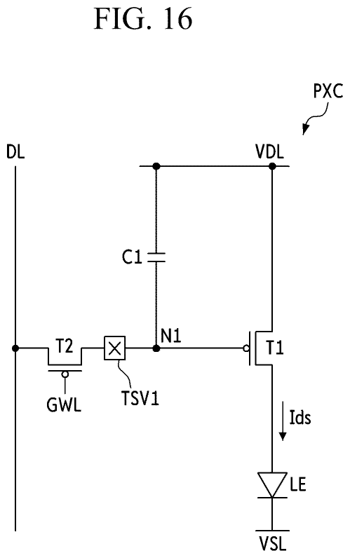

FIG. 16 is a pixel circuit diagram according to one or more embodiments of the present disclosure.

Referring to FIG. 16, the pixel circuit PXC of the sub-pixels SP1, SP2, and SP3 may be connected to the first scan line GWL and the data line DL. The pixel circuit PXC may be applied to both the first panel portion and the second panel portion. Further, the pixel circuit PXC may be connected to the first driving voltage line VSL to which the first driving voltage VSS corresponding to a low potential voltage is applied, and the second driving voltage line VDL to which the second driving voltage VDD corresponding to a high potential voltage is applied. That is, the first driving voltage line VSL may be a low potential voltage line and the second driving voltage line VDL may be a high potential voltage line. In this case, the first driving voltage VSS may be lower than the second driving voltage VDD.

The pixel circuit PXC of the sub-pixels SP1, SP2, and SP3 includes a plurality of transistors T1 and T2, a light emitting element LE, and a first capacitor C1.

The light emitting element LE emits light in response to a driving current Ids flowing through the channel of the first transistor T1. The emission amount of the light emitting element LE may be proportional to the driving current Ids. The light emitting element LE may be located between the first transistor T1 and the first driving voltage line VSL. The first electrode of the light emitting element LE may be connected to the drain electrode of the first transistor T1, and the second electrode of the light emitting element LE may be connected to the first driving voltage line VSL. The first electrode of the light emitting element LE may be an anode electrode, and the second electrode of the light emitting element LE may be a cathode electrode. The light emitting element LE may be an organic light emitting diode (OLED) including a first electrode, a second electrode, and an organic light emitting layer located between the first electrode and the second electrode, but is not limited thereto. For example, the light emitting element LE may be an inorganic light emitting element including a first electrode, a second electrode, and an inorganic semiconductor located between the first electrode and the second electrode, in which case the light emitting element LE may be a micro light emitting diode.

The first transistor T1 may be a driving transistor that controls a source-drain current Ids (hereinafter referred to as “driving current”) flowing between the source electrode and the drain electrode according to a voltage applied to the gate electrode of the first transistor T1. The first transistor T1 includes a gate electrode connected to a first node N1, a source electrode connected to the second driving voltage line VDL, and a drain electrode connected to the light emitting element LE.

The second transistor T2 may be located between one electrode of the first capacitor C1 and the data line DL. The second transistor T2 is turned on by the write scan signal of the first scan line GWL to connect the one electrode of the first capacitor C1 to the data line DL. Accordingly, the data voltage of the data line DL may be applied to the one electrode of the first capacitor C1. The second transistor T2 includes a gate electrode connected to the first scan line GWL, a source electrode connected to the data line DL, and a drain electrode connected to the one electrode of the first capacitor C1.

The first capacitor C1 is formed between the first node N1 and the second driving voltage line VDL. The first capacitor C1 includes one electrode connected to the drain electrode of the second transistor T2 and the first node N1 and the other electrode connected to the second driving voltage line VDL. The first node N1 is a contact point between the gate electrode of the first transistor T1, the source electrode of the second transistor T2, and the other electrode of the first capacitor C1.

According to one or more embodiments, in the display device, the first transistor T1, the light emitting element LE, the first driving voltage line VSL, and the second driving voltage line VDL may be located in the display unit DP, and the second transistor T2 may be located in the first driver DRP1. The second transistor T2 may be formed on the first single crystal semiconductor substrate 110 of the first driver DRP1, and the first transistor T1 may be formed on the second single crystal semiconductor substrate 210 of the display unit DP. The second transistor T2 may be connected to the first node N1 through the first through hole TSV1 formed in the second single crystal semiconductor substrate 210. Accordingly, the data line DL and the first scan line GWL may be located in the first pixel circuit unit 810 of the first driver DRP1, and the driving voltage lines VSL and VDL may be located in the second pixel circuit unit 820 of the display unit DP.

Each of the first and second transistors T1 and T2 may be a metal-oxide-semiconductor field effect transistor (MOSFET). For example, each of the first and second transistors T1 and T2 may be a p-type MOSFET, but is not limited thereto. Each of the first and second transistors T1 and T2 may be an n-type MOSFET. Alternatively, some of the first and second transistors T1 and T2 may be p-type MOSFETs, and each of the remaining transistors may be an n-type MOSFET.

Although FIG. 16 illustrates that the pixel circuit PXC of the sub-pixels SP1, SP2, and SP3 includes two transistors T1 and T2 and one capacitor C1, the equivalent circuit diagram of the sub-pixel SP may not be limited to that shown in FIG. 16. For example, the number of transistors and capacitors of the pixel circuit PXC may be larger than that shown in FIG. 16.

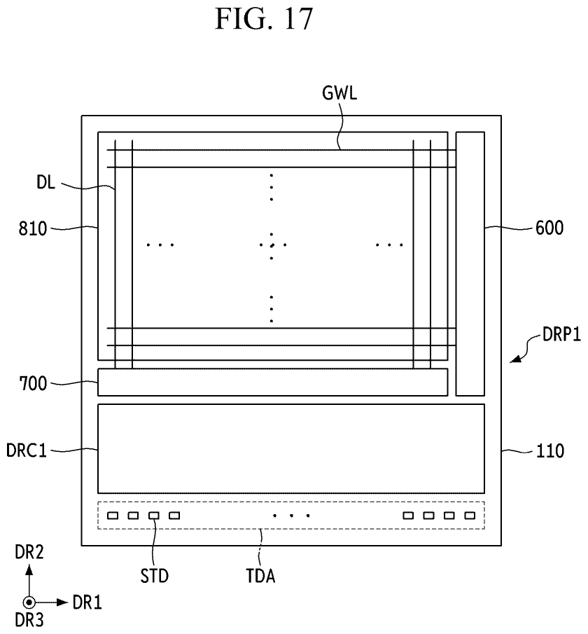

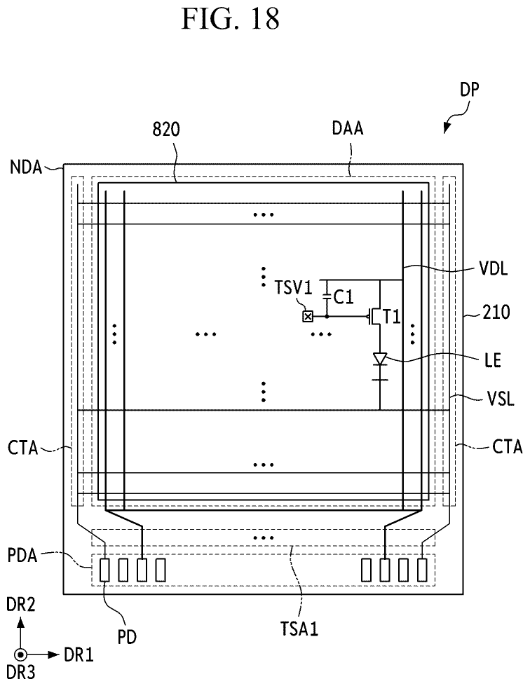

FIG. 17 is a drawing showing wires located in a driver of a first panel portion according to one or more embodiments of the present disclosure. FIG. 18 is a drawing showing connection between a pixel circuit and wires located in a display unit of a first panel portion according to one or more embodiments of the present disclosure.

Referring to FIGS. 17 and 18, in the first driver DRP1 of the display device, the plurality of first scan lines GWL and the plurality of data lines DL may be located.

The plurality of first scan lines GWL may extend in the first direction DR1 and may be spaced (e.g., spaced apart) from each other in the second direction DR2, and the plurality of data lines DL may extend in the second direction DR2 and may be spaced (e.g., spaced apart) from each other in the first direction DR1. The plurality of data lines DL may extend from the data driver 700 located on the lower side of the display area DAA, and the plurality of first scan lines GWL may extend from the gate driver 600 located on the right side of the display area DAA. The plurality of first scan lines GWL and data lines DL may be respectively connected to the second transistors T2 formed in the first pixel circuit unit 810.

In the display unit DP of the display device, the first driving voltage line VSL and the second driving voltage line VDL may be located.

The first driving voltage line VSL may include a stem line located in the common electrode contact area CTA, and a plurality of horizontal lines branched from the stem line in the first direction DR1 and located in the display area DAA. The stem line of the first driving voltage line VSL may be connected to the pad PD of the pad area PDA. The second driving voltage line VDL may include a plurality of vertical lines located in the display area DAA, and a horizontal line connected to the plurality of vertical lines in the non-display area NDA. The horizontal line of the second driving voltage line VDL may be connected to the pad PD of the pad area PDA. In the display area DAA, the plurality of horizontal lines of the first driving voltage line VSL and the plurality of vertical lines of the second driving voltage line VDL may be located in a mesh type.

The plurality of first transistors T1 and first capacitors C1 may be formed in the second pixel circuit unit 820 located in the display area DAA. The first transistor T1 and the first capacitor C1 may be electrically connected to the second transistor T2 of the first driver DRP1 through the first through hole TSV1. The first transistor T1 may be electrically connected to the light emitting element LE located in a display element layer EML (see FIG. 24) to be described later. Further, the first transistor T1 may be electrically connected to the second driving voltage line VDL, and the light emitting element LE may be electrically connected to the first driving voltage line VSL. The first transistor T1, the second transistor T2, and the first capacitor C1 may constitute the pixel circuit PXC corresponding to each of the sub-pixels SP1, SP2, and SP3 of the display device, and they may be respectively connected to the driving voltage lines VSL and VDL.

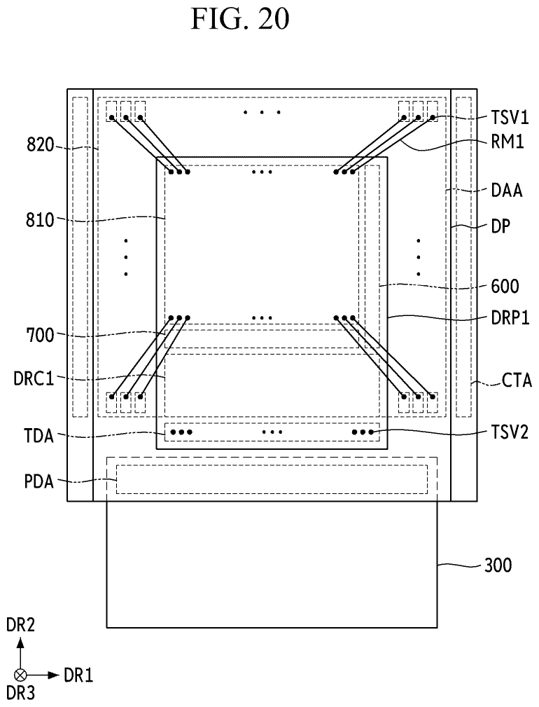

FIG. 19 is a schematic cross-sectional view of a first panel portion according to one or more embodiments of the present disclosure. FIG. 20 is a schematic view showing the rear surface of the first panel portion according to one or more embodiments of the present disclosure. FIG. 19 illustrates a schematic connection relationship of routing wires that electrically connect a display unit and a driver, and FIG. 20 illustrates arrangement of a through hole and routing wires when viewed from a rear surface of a display device.

Referring to FIGS. 19 and 20, the display device according to one or more embodiments may include the first driver DRP1 including the first single crystal semiconductor substrate 110 and a first driving circuit layer 120 located on the first single crystal semiconductor substrate 110; and the display unit DP including the second single crystal semiconductor substrate 210 and the second pixel circuit unit 820 and the display layer 230 located on the second single crystal semiconductor substrate 210. The display device may include the two different single crystal semiconductor substrates 110 and 210 overlapping each other in a third direction DR3, which is the thickness direction of the display device.

The first driver DRP1 may include circuit elements necessary for light emission of the light emitting elements included in the display layer 230 of the display unit DP. As described above, the first driving circuit layer 120 of the first driver DRP1 may include the first driving circuit unit DRC1, the gate driver 600, the data driver 700, the first pixel circuit unit 810 and so forth, and the circuit elements constituting them, such as the second transistor T2 and the scan transistor, may be formed as CMOS elements on the first single crystal semiconductor substrate 110. Further, the plurality of first scan lines GWL and data lines DL may be located in the first driving circuit layer 120.

The display unit DP may include some of the circuit elements required for light emission of the light emitting elements and the plurality of light emitting elements that emit light to display an image of the display device. The display unit DP may include the second pixel circuit unit 820 in which circuit elements constituting the pixel circuit PXC are located. The second pixel circuit unit 820 may include some of the circuit elements constituting the pixel circuit, such as the first transistor T1 and the first capacitor C1 of FIG. 16, and the plurality of driving voltage lines VSL and VDL may be located the second pixel circuit unit 820. The first transistor T1 may be formed as a CMOS transistor in the second single crystal semiconductor substrate 210. The light emitting elements may be electrically connected to the circuit elements formed in the second pixel circuit unit 820 of the display unit DP, and the first pixel circuit unit 810 or the first driving circuit layer 120 of the first driver DRP1 to emit light.

According to one or more embodiments, in the display device, in a plan view, the area of the first driver DRP1 or the first single crystal semiconductor substrate 110 may be smaller than the area of the display unit DP or the second single crystal semiconductor substrate 210. A plurality of transistors formed in the first driver DRP1 may be formed through a semiconductor micro-process, and thus may have a very small size and/or line width. The first driver DRP1 may have a large number of circuit elements located with a high integration density, and power consumption may be reduced due to the miniaturization of the elements.

In addition, because the first driver DRP1 includes only the circuit elements formed as CMOS elements on the first single crystal semiconductor substrate 110 and does not include light emitting elements, the first driver DRP1 only needs to secure a space for accommodating the elements formed by the micro-process. It still works even if the first single crystal semiconductor substrate 110 has a smaller area than the second single crystal semiconductor substrate 210, and a large number of first drivers DRP1 may be manufactured on a single wafer substrate on which the process of forming the first driving circuit layer 120 is performed, so that the manufacturing yield may be improved. In particular, because a high-cost semiconductor process is performed to manufacture the first driver DRP1, such improvement in the manufacturing yield of the first driver DRP1 may lead to cost reduction. Further, in the display unit DP, a large number of light emitting elements may be formed on the second single crystal semiconductor substrate 210 having a relatively large area, enabling the implementation of a high-resolution display device.

The display device may include a connection wiring layer CLL located between the second single crystal semiconductor substrate 210 of the display unit DP and the first driving circuit layer 120 of the first driver DRP1. The connection wiring layer CLL may be located on the bottom surface of the second single crystal semiconductor substrate 210. The plurality of routing wires RM1 and RM2 may be partially located in the connection wiring layer CLL. The routing wires RM1 and RM2 may connect the second pixel circuit unit 820 of the display unit DP and the circuit board 300 to the first driver DRP1. The first driving circuit layer 120 of the first driver DRP1 may be electrically connected to the display unit DP and the circuit board 300 through the routing wires RM1 and RM2 of the connection wiring layer CLL to transmit an electrical signal for light emission.

The first routing wire RM1 may be connected to the second pixel circuit unit 820 of the display unit DP and the first pixel circuit unit 810 of the first driver DRP1. In one or more embodiments, the display device may include the plurality of first through holes TSV1 located to correspond to the sub-pixels SP1, SP2, and SP3 of the display unit DP, and the first routing wire RM1 may be located in the first through holes TSV1 to connect the first pixel circuit unit 810 and the second pixel circuit unit 820. For example, the first routing wire RM1 may connect the second transistor T2 of the first pixel circuit unit 810 and the first transistor T1 of the second pixel circuit unit 820. The first through hole TSV1 may be located throughout the second pixel circuit unit 820 of the display unit DP having a large area, whereas the first pixel circuit unit 810 of the first driver DRP1 may have a relatively small area. The first routing wire RM1 may include conductive vias RVA1 (see FIG. 24) located throughout the display unit DP having the large area and a connection wire RML1 (see FIG. 24) connecting them to the first pixel circuit unit 810 having the small area. The distance between the first routing wire RM1 and the neighboring first routing wire RM1 may be narrower in the portion overlapping the first driver DRP1 than in the portion overlapping the display area DAA in a plan view.

In one or more embodiments, some of the first through holes TSV1 may overlap the first driver DRP1 in the thickness direction (e.g., the third direction DR3), and others may not overlap the first driver DRP1 in the thickness direction (e.g., the third direction DR3). As for the first routing wire RM1 located in the first through holes TSV1 that do not overlap the first driver DRP1, a part of the connection wire RML1 (see FIG. 24) may not overlap the first driver DRP1. However, the arrangement of the first through holes TSV1 may vary according to the location of the layer where the connection wire RML1 of the first routing wires RM1 is located.

According to one or more embodiments, the number of first through holes TSV1 may be equal to the number of the sub-pixels SP1, SP2, and SP3 located in the display area DAA. For example, the plurality of sub-pixels SP1, SP2, and SP3 may be arranged along the first direction DR1 and the second direction DR2 in the display area DAA. The first through holes TSV1 may also be arranged along the first direction DR1 and the second direction DR2 and may correspond one-to-one to the respective subpixels SP1, SP2, and SP3. The first through holes TSV1 may be formed to respectively overlap the sub-pixels SP1, SP2, and SP3. The number of first routing wires RM1 may be equal to the number of sub-pixels SP1, SP2, and SP3.

The plurality of second through holes TSV2 may be located in the first through hole area TSA1 of the display unit DP and may be formed to overlap the signal terminal area TDA of the first driver DRP1. The second routing wire RM2 connected to the signal terminal STD of the first driver DRP1 may be located in the second through holes TSV2. Unlike the first through hole TSV1, the second through hole TSV2 may be formed to overlap each signal terminal STD of the first driver DRP1. Accordingly, the second routing wire RM2 may also be located to correspond to and overlap each signal terminal STD. The second routing wire RM2 may be a wire that transmits a signal applied from the circuit board 300 to the first driver DRP1.

Hereinafter, the structure of the first driving circuit layer 120 of the first driver DRP1 and the display layer 230 of the display unit DP will be described in detail with reference to other drawings.

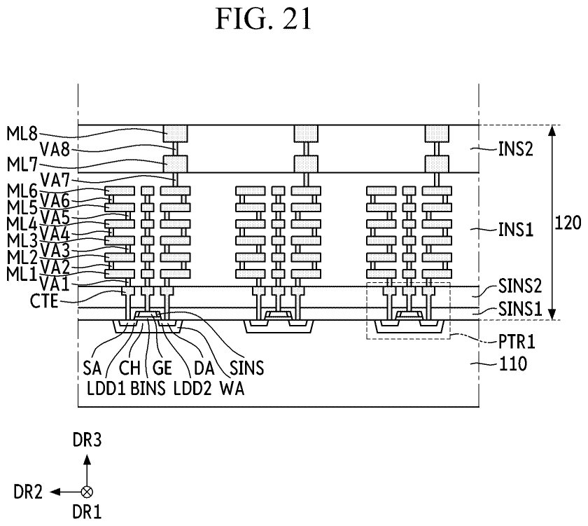

FIG. 21 is a schematic cross-sectional view of a driver of a first panel portion according to one or more embodiments of the present disclosure.

Referring to FIG. 21, the first driver DRP1 may include the first single crystal semiconductor substrate 110 and the first driving circuit layer 120 located on the first single crystal semiconductor substrate 110.

The first single crystal semiconductor substrate 110 may be a silicon substrate, a germanium substrate, or a silicon-germanium substrate. The first single crystal semiconductor substrate 110 may be a substrate doped with a first type impurity. A plurality of well regions WA may be located on the top surface of the first single crystal semiconductor substrate 110. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of a first transistor PTR1, a drain region DA corresponding to the drain electrode of the first transistor PTR1, and a channel region CH located between the source region SA and the drain region DA.

A lower insulating film BINS may be located between a gate electrode GE and the well region WA. A side insulating film SINS may be located on the side surface of the gate electrode GE. The side insulating film SINS may be located on the lower insulating film BINS.

Each of the source region SA and the drain region DA may be a region doped with the first type impurity. The gate electrode GE of the first transistor PTR1 may overlap the well region WA in the third direction DR3. The channel region CH may overlap the gate electrode GE in the third direction DR3. The source region SA may be located on one side of the gate electrode GE, and the drain region DA may be located on the other side of the gate electrode GE.

Each of the plurality of well regions WA further includes a first low-concentration impurity region LDD1 located between the channel region CH and the source region SA, and a second low-concentration impurity region LDD2 located between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the first transistors PTR1 may increase, so that punch-through and hot carrier phenomena that might be caused by a short channel may be reduced or prevented.

The first single crystal semiconductor substrate 110 may include the plurality of first transistors PTR1 constituting a plurality of circuit elements of the first driver DRP1. The first transistors PTR1 formed on the first single crystal semiconductor substrate 110 may constitute the first driving circuit unit DRC1, the gate driver 600, the data driver 700, and the first pixel circuit unit 810.

When the first driving circuit layer 120 is formed on a silicon wafer substrate, a process of reducing the thickness of the first single crystal semiconductor substrate 110 may be performed. The first single crystal semiconductor substrate 110 may have a thickness less than that of a wafer substrate on which a semiconductor process for forming the first driving circuit layer 120 is performed. In one or more embodiments, the thickness of the first single crystal semiconductor substrate 110 may be 100 μm or less, for example, in the range of 80 μm to 100 μm.

The first driving circuit layer 120 may include a first semiconductor insulating layer SINS1, a second semiconductor insulating layer SINS2, a plurality of contact electrodes CTE, a first interlayer insulating layer INS1, a second interlayer insulating layer INS2, a plurality of conductive layers ML1 to ML8, and a plurality of vias VA1 to VA8. The first driving circuit layer 120 may include wires electrically connected to the plurality of first transistors PTR1 included in the first single crystal semiconductor substrate 110.

The first semiconductor insulating layer SINS1 and the second semiconductor insulating layer SINS2 may be located on the first single crystal semiconductor substrate 110. The first semiconductor insulating layer SINS1 may be an insulating layer located on the first single crystal semiconductor substrate 110, and the second semiconductor insulating layer SINS2 may be an insulating layer located on the gate electrode GE of the first transistor PTR1 and the first semiconductor insulating layer SINS1. The first semiconductor insulating layer SINS1 and the second semiconductor insulating layer SINS2 may include a silicon carbon nitride (SiCN) and/or silicon oxide (SiOₓ)-based inorganic film, but are not limited thereto. In the drawing, the first semiconductor insulating layer SINS1 and the second semiconductor insulating layer SINS2 are each shown as a single layer having a suitable thickness, but are not limited thereto. The first semiconductor insulating layer SINS1 and the second semiconductor insulating layer SINS2 may have a structure in which one or more layers are stacked on top of each other.

The plurality of contact electrodes CTE may be located on the first single crystal semiconductor substrate 110. The plurality of contact electrodes CTE may be connected to any one of the gate electrodes GE, the source region SA, and the drain region DA of each first transistor PTR1 formed on the first single crystal semiconductor substrate 110 through a hole penetrating the semiconductor insulating layers SINS1 and SINS2. The plurality of contact electrodes CTE may include copper (Cu), aluminum (Al), tungsten (W), molybdenum (Mo), chromium (Cr), gold (Au), titanium (Ti), nickel (Ni), and/or neodymium (Nd), and/or an alloy including one or more of them. The top surfaces of the plurality of contact electrodes CTE may be exposed without being covered by the semiconductor insulating layers SINS1 and SINS2.

The first interlayer insulating layer INS1 may be located on the plurality of contact electrodes CTE and the semiconductor insulating layers SINS1 and SINS2. The second interlayer insulating layer INS2 may be located on the first interlayer insulating layer INS1. Each of the first interlayer insulating layer INS1 and the second interlayer insulating layer INS2 may include silicon carbonitride (SiCN) and/or a silicon oxide (SiOₓ)-based inorganic film, but is not limited thereto. Although it is illustrated in the drawings that each of the first interlayer insulating layer INS1 and the second interlayer insulating layer INS2 is formed as a single layer, the present disclosure is not limited thereto. Each of the first interlayer insulating layer INS1 and the second interlayer insulating layer INS2 may have a structure in which one or more layers are stacked on top of each other, and may be located between a plurality of first to eighth conductive layers ML1 to ML8 to be described later.

The first to eighth conductive layers ML1 to ML8 and first to eighth vias VA1 to VA8 may be electrically connected to the plurality of contact electrodes CTE to form the first driving circuit unit DRC1 or the data driver 700 of the first driver DRP1. The plurality of first transistors PTR1 formed in the first single crystal semiconductor substrate 110 may be electrically connected to each other through the first to eighth conductive layers ML1 to ML8 and the first to eighth vias VA1 to VA8, and may form the data driver 700 and the first driving circuit unit DRC1 of the first driver DRP1.

The first conductive layer ML1 may be connected to the contact electrode CTE through the first via VA1. The first conductive layer ML1 may be located above the contact electrode CTE, and the first via VA1 may be located between the first conductive layer ML1 and the contact electrode CTE to be in contact with both of them. The second conductive layer ML2 may be connected to the first conductive layer ML1 through the second via VA2. The second conductive layer ML2 may be located above the first conductive layer ML1, and the second via VA2 may be located between the first conductive layer ML1 and the second conductive layer ML2 to be in contact with both of them.

The third conductive layer ML3 may be connected to the second conductive layer ML2 through the third via VA3. The fourth conductive layer ML4 may be connected to the third conductive layer ML3 through the fourth via VA4, the fifth conductive layer ML5 may be connected to the fourth conductive layer ML4 through the fifth via VA5, and the sixth conductive layer ML6 may be connected to the fifth conductive layer ML5 through the sixth via VA6. The third conductive layer ML3, the fourth conductive layer ML4, the fifth conductive layer ML5, and the sixth conductive layer ML6 may be sequentially located above the second conductive layer ML2, and the third via VA3, the fourth via VA4, the fifth via VA5, and the sixth via VA6 may be located between them. The third to sixth vias VA3 to VA6 may be in contact with different metal layers located above and below them, respectively. The seventh via VA7 may be located on the sixth conductive layer ML6. The seventh via VA7 may be in contact with the seventh conductive layer ML7 located thereon and the sixth conductive layer ML6.

The first to sixth conductive layers ML1 to ML6 and the first to seventh vias VA1 to VA7 may be located in the first interlayer insulating layer INS1. The first to sixth conductive layers ML1 to ML6 and the first to seventh vias VA1 to VA7 may constitute a first driving circuit layer located in the first interlayer insulating layer INS1 of the first driving circuit layer 120.

The seventh conductive layer ML7 may be connected to the sixth conductive layer ML6 through the seventh via VA7. The seventh conductive layer ML7 may be located above the sixth conductive layer ML6 and the first interlayer insulating layer INS1, and the seventh via VA7 may be located between the sixth conductive layer ML6 and the seventh conductive layer ML7 to be in contact with both of them. The eighth conductive layer ML8 may be connected to the seventh conductive layer ML7 through the eighth via VA8. The eighth conductive layer ML8 is located above the seventh conductive layer ML7, and the eighth via VA8 may be located between the seventh conductive layer ML7 and the eighth conductive layer ML8 to be in contact with both of them. The eighth conductive layer ML8 may have a top surface exposed without being covered by the second interlayer insulating layer INS2, and may be electrically connected to the routing wire RM located in the display unit DP.

The seventh conductive layer ML7, the eighth via VA8, and the eighth conductive layer ML8 may be located in the second interlayer insulating layer INS2. The seventh conductive layer ML7, the eighth via VA8, and the eighth conductive layer ML8 may constitute a second driving circuit layer located in the second interlayer insulating layer INS2 of the first driving circuit layer 120.

In the drawings, although the first to eighth conductive layers ML1 to ML8 and the first to eighth vias VA1 to VA8 are illustrated as being sequentially stacked on top of each other, their arrangement and connection may be modified in various ways according to the circuits of the data driver 700 and the first driving circuit unit DRC1 of the first driver DRP1. The connection structure shown in the drawings is nothing more than an example, and the connection of the first driving circuit layer 120 located in the first driver DRP1 of the display device is not limited thereto. In addition, the first driving circuit layer 120 may not necessarily include the first to eighth conductive layers ML1 to ML8 and the first to eighth vias VA1 to VA8, and some of these layers may be omitted or more layers may be provided.

The first to eighth conductive layers ML1 to ML8 and the first to eighth vias VA1 to VA8 may include substantially the same material. For example, the first to eighth conductive layers ML1 to ML8 and the first to eighth vias VA1 to VA8 may include copper (Cu), aluminum (Al), tungsten (W), molybdenum (Mo), chromium (Cr), gold (Au), titanium (Ti), nickel (Ni), and/or neodymium (Nd), and/or an alloy including one or more of them.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å. The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å. The thickness of each of the seventh via VA7 and the eighth via VA8 may be approximately 6000 Å.

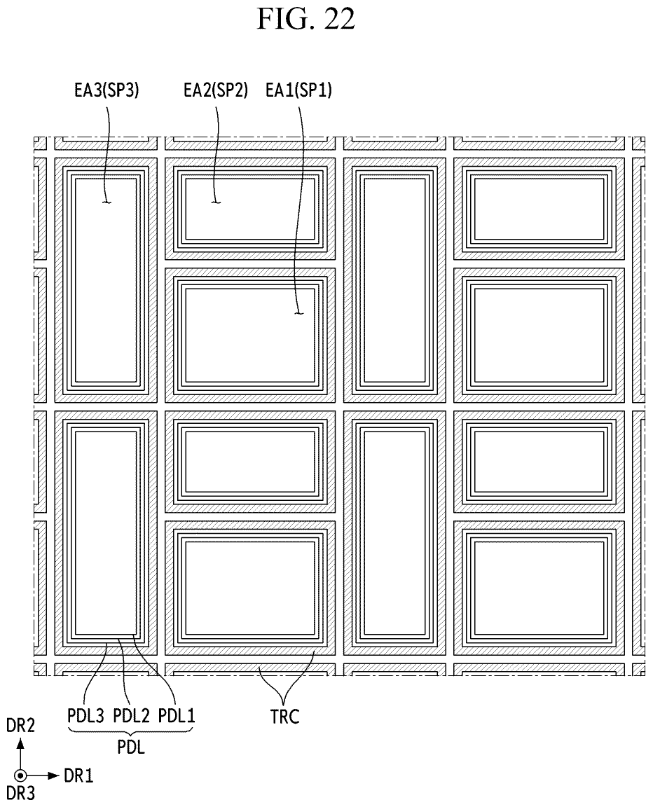

FIG. 22 is a plan view showing a pixel defining film, and first electrodes and emission areas of a plurality of sub-pixels located in a display area of a display unit of a first panel portion according to one or more embodiments of the present disclosure.

Referring to FIG. 22, each of the plurality of pixels PX may include a first sub-pixel SP1, a second sub-pixel SP2, and a third sub-pixel SP3. The first to third sub-pixels SP1, SP2, and SP3 may include emission areas EA1, EA2, and EA3, respectively. For example, the first sub-pixel SP1 may include the first emission area EA1, the second sub-pixel SP2 may include the second emission area EA2, and the third sub-pixel SP3 may include the third emission area EA3.

Each of the first emission area EA1, the second emission area EA2, and the third emission area EA3 may have, in a plan view, a quadrilateral shape such as a rectangle, a square, or a diamond. For example, the third emission area EA3 may have a rectangular shape, in a plan view, having a short side in the first direction DR1 and a long side in the second direction DR2. In addition, each of the second emission area EA2 and the first emission area EA1 may have a rectangular shape, in a plan view, having a long side in the first direction DR1 and a short side in the second direction DR2.

Each of the first emission area EA1, the second emission area EA2, and the third emission area EA3 may be an area defined by a pixel defining film PDL. For example, each of the first emission area EA1, the second emission area EA2, and the third emission area EA3 may be an area defined by a first pixel defining film PDL1.

The length of the third emission area EA3 in the first direction DR1 may be less than the length of the first emission area EA1 in the first direction DR1, and may be less than the length of the second emission area EA2 in the first direction DR1. The length of the first emission area EA1 in the first direction DR1 and the length of the second emission area EA2 in the first direction DR1 may be substantially the same.

In each of the plurality of pixels PX, the first emission area EA1 and the second emission area EA2 may be adjacent to each other in the second direction DR2. Further, the first emission area EA1 and the third emission area EA3 may be adjacent to each other in the first direction DR1. Further, the second emission area EA2 and the third emission area EA3 may be adjacent to each other in the first direction DR1. The area of the first emission area EA1, the area of the second emission area EA2, and the area of the third emission area EA3 may be different.

Although it is illustrated in the drawing that each of the first emission area EA1, the second emission area EA2, and the third emission area EA3 has a rectangular shape in a plan view, the present disclosure is not limited thereto. For example, each of the first emission area EA1, the second emission area EA2, and the third emission area EA3 may have a polygonal shape other than a quadrilateral shape, a circular shape, or an elliptical shape in a plan view.

The first emission area EA1 may emit light of a first color, the second emission area EA2 may emit light of a second color, and the third emission area EA3 may emit light of a third color. Here, the light of the first color may be light of a red wavelength band, the light of the second color may be light of a green wavelength band, and the light of the third color may be light of a blue wavelength band. For example, the blue wavelength band may be a wavelength band of light whose main peak wavelength is in the range of approximately 370 nm to 460 nm, the green wavelength band may be a wavelength band of light whose main peak wavelength is in the range of approximately 480 nm to 560 nm, and the red wavelength band may be a wavelength band of light whose main peak wavelength is in the range of approximately 600 nm to 750 nm.

A first electrode AND (e.g., see FIG. 24) of the light emitting element may have a rectangular shape in a plan view. The planar shape of the first electrode AND of the light emitting element may be different in the first sub-pixel SP1, the second sub-pixel SP2, and the third sub-pixel SP3. For example, the first electrode AND of the first sub-pixel SP1 and the first electrode AND of the second sub-pixel SP2 may have a rectangular planar shape having a long side in the first direction DR1 and a short side in the second direction DR2. The first electrode AND of the third sub-pixel SP3 may have a rectangular shape, in a plan view, having a short side in the first direction DR1 and a long side in the second direction DR2. The length of the first electrode AND of the third sub-pixel SP3 in the first direction DR1 may be less than the length of the first electrode AND of each of the first sub-pixel SP1 and the second sub-pixel SP2 in the first direction DR1 or the second direction DR2. The length of the first electrode AND of the first sub-pixel SP1 in the second direction DR2 may be greater than the length of the first electrode AND of the second sub-pixel SP2 in the second direction DR2.

The first electrode AND of the light emitting element may be connected to a reflective electrode layer RL (see FIG. 24) via an electrode via VAP. The electrode via VAP may overlap the first pixel defining film PDL1, a second pixel defining film PDL2, and a third pixel defining film PDL3 in the third direction DR3.

At least one trench TRC may be a structure for cutting off at least one charge generation layer of a light emitting stack IL between the neighboring emission areas EA1, EA2, and EA3 (see FIG. 24). At least one trench TRC may be located between the first emission area EA1 and the second emission area EA2, between the first emission area EA1 and the third emission area EA3, and between the second emission area EA2 and the third emission area EA3. More specifically, at least one trench TRC may be located between the first electrode AND of the first sub-pixel SP1 and the first electrode AND of the second sub-pixel SP2, between the first electrode AND of the first sub-pixel SP1 and the first electrode AND of the third sub-pixel SP3, and between the first electrode AND of the second sub-pixel SP2 and the first electrode AND of the third sub-pixel SP3.

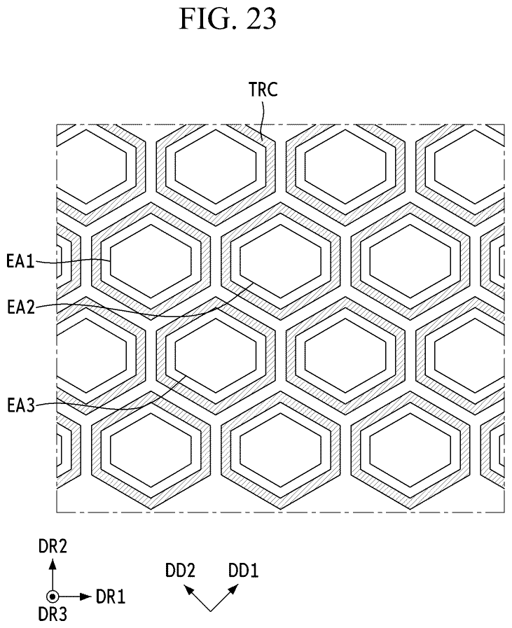

FIG. 23 is a plan view showing a pixel defining film, and first electrodes and emission areas of a plurality of sub-pixels located in a display area of a display unit of a first panel portion according to one or more embodiments.

Referring to FIG. 23, the embodiment of FIG. 11 is substantially the same as the embodiment of FIG. 22 except that the planar shapes of the first emission area EA1, the second emission area EA2, and the third emission area EA3 are different from those of the embodiment of FIG. 22, description overlapping with the embodiment of FIG. 22 will be omitted.

The first emission area EA1, the second emission area EA2, and the third emission area EA3 may be located in a hexagonal structure having a hexagonal shape in a plan view. In this case, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

Although it is illustrated in FIGS. 22 and 23 that each of the plurality of pixels PX includes the three emission areas EA1, EA2, and EA3, the present disclosure is not limited thereto. That is, each of the plurality of pixels PX may include four emission areas.

In addition, the arrangement of the emission areas of the plurality of pixels PX is not limited to that illustrated in the drawing. For example, the emission areas of the plurality of pixels PX may be located in a stripe structure in which the emission areas are arranged along the first direction DR1, a PENTILE® structure in which the emission areas are arranged in a diamond shape, or a hexagonal structure in which the emission areas having, in a plan view, a hexagonal shape are arranged side by side.

FIG. 24 is a cross-sectional view showing a part of a display unit of a first panel portion according to one or more embodiments. FIG. 24 shows a schematic cross-sectional structure of a first through hole area of a non-display area and a display area.

Referring to FIG. 24, the display unit DP may include a semiconductor backplane SBP, a pixel circuit backplane EBP, the display element layer EML, an encapsulation layer TFE, an adhesive layer ADL, an optical layer OPL, and a cover layer DCL. The semiconductor backplane SBP and the pixel circuit backplane EBP of the display unit DP may constitute the second pixel circuit unit 820. The display element layer EML, the encapsulation layer TFE, the adhesive layer ADL, and the optical layer OPL of the display unit DP may constitute the display layer 230 In one or more embodiments, the display unit DP may further include a polarizing plate located on the cover layer DCL. The connection wiring layer CLL may be located between the first single crystal semiconductor substrate 110 and the second single crystal semiconductor substrate 210 of the semiconductor backplane SBP. Alternatively, the connection wiring layer CLL may be located between the display element layer EML and the first single crystal semiconductor substrate 110.

The semiconductor backplane SBP includes the second single crystal semiconductor substrate 210 including a plurality of second transistors PTR2, a plurality of semiconductor insulating films located on the plurality of second transistors PTR2, and the plurality of contact electrodes CTE respectively electrically connected to the plurality of pixel transistors. The plurality of second transistors PTR2 may be the first transistor T1 constituting the pixel circuit.

The second single crystal semiconductor substrate 210 may be a silicon substrate, a germanium substrate, or a silicon-germanium substrate. The second single crystal semiconductor substrate 210 may be a substrate doped with an impurity. The plurality of well regions WA may be located on the top surface of the second single crystal semiconductor substrate 210. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

The second single crystal semiconductor substrate 210 may include the plurality of second transistors PTR2, similarly to the first single crystal semiconductor substrate 110. The structure of the second transistor PTR2 may be the same as that of the first transistor PTR1, and therefore, a detailed description thereof will be omitted.

In the display device, wafer substrates on which the first transistor PTR1 formed on the first single crystal semiconductor substrate 110 of the first driver DRP1, and the second transistor PTR2 formed on the second single crystal semiconductor substrate 210 of the display unit DP are formed may be different. According to one or more embodiments, in the display device, the first transistor PTR1 formed on the first single crystal semiconductor substrate 110 and the second transistor PTR2 formed on the second single crystal semiconductor substrate 210 may have different sizes, line widths, and/or the like.

For example, in the display device, the minimum line width of the first transistor PTR1 formed on the first single crystal semiconductor substrate 110 may be less than the minimum line width of the second transistor PTR2 formed on the second single crystal semiconductor substrate 210. The semiconductor process performed on a first wafer substrate for the formation of the first transistor PTR1 is a process having higher resolution than the semiconductor process performed on a second wafer substrate for the formation of the second transistor PTR2, and thus the size of an element such as a manufactured transistor may be smaller. In other words, the semiconductor process performed on the first wafer substrate may be a finer process than the semiconductor process performed on the second wafer substrate.

As described above, the first single crystal semiconductor substrate 110 of the first driver DRP1 may have a smaller area in a plan view than the second single crystal semiconductor substrate 210 of the display unit DP, and small-sized elements may be located with a high integration density to reduce power consumption and improve manufacturing yield. On the other hand, the second single crystal semiconductor substrate 210 of the display unit DP may have a larger area in a plan view than the first single crystal semiconductor substrate 110, and a process with a relatively large linewidth may be performed. The second transistors PTR2 located in the second single crystal semiconductor substrate 210 may be formed in a larger area than when formed in the first single crystal semiconductor substrate 110, and the second transistors PTR2 constituting the pixel circuit may not require a high integration density. Accordingly, the semiconductor process performed on the first wafer substrate may be performed as a high-cost process having a small line width, and the semiconductor process performed on the second wafer substrate may be performed as a low-cost process having a relatively large line width.

In one or more embodiments, the lengths of the channel regions CH of the plurality of transistors PTR1 and PTR2 may be different from each other, and the minimum line width or a length of the channel region CH of the first transistor PTR1 may be less than the minimum line width or a length of the channel region CH of the second transistor PTR2. The minimum line width or the length of the channel region CH of the first transistor PTR1 may be less than or equal to 100 nm, or may range from 2 nm to 80 nm. The minimum line width or the length of the channel region CH of the second transistor PTR2 may be greater than or equal to 100 nm, or may range from 100 nm to 5 μm.

The second single crystal semiconductor substrate 210 may include the plurality of first through holes TSV1 spaced (e.g., spaced apart) from each other. The first through hole TSV1 may penetrate the second single crystal semiconductor substrate 210 from the top surface to the bottom surface thereof. A first conductive via RVA1 of the first routing wire RM1 may be located in the first through hole TSV1. The first through hole TSV1 may form the connection path of the first routing wires RM1 that electrically connect the first pixel circuit unit 810 of the first driver DRP1 to the second pixel circuit unit 820 of the display unit DP.

The second single crystal semiconductor substrate 210 may include the plurality of second through holes TSV2 formed in the non-display area NDA, and the second conductive vias RVA2 of the second routing wires RM2 may be located in the second through holes TSV2, respectively. The circuit board 300 may be electrically connected to the signal terminal STD of the first driver DRP1 via the second routing wire RM2. The second conductive via RVA2 may form a connection path of the second routing wires RM2 connecting the circuit board 300 and the signal terminal STD of the first driver DRP1.

In one or more embodiments, the through holes TSV1 and TSV2 of the second single crystal semiconductor substrate 210 may be formed through a through silicon via (TSV) process in which a hole that penetrates the wafer substrate is formed. Through the through holes TSV1 and TSV2 formed in the second single crystal semiconductor substrate 210, the display layer 230 and the first driver DRP1 may be electrically connected to each other through the routing wires RM1 and RM2 without an additional wire.

A process of reducing the thickness of the second single crystal semiconductor substrate 210 may be performed after the first driver DRP1 is bonded onto the silicon wafer substrate. The second single crystal semiconductor substrate 210 may have a thickness less than that of the wafer substrate on which a process for forming conductive layers is performed. In one or more embodiments, the thickness of the second single crystal semiconductor substrate 210 may be 100 μm or less, for example, in the range of 80 μm to 100 μm.

The semiconductor backplane SBP and the pixel circuit backplane EBP may be located on the second single crystal semiconductor substrate 210. Some of the pixel circuit backplane EBP and the semiconductor backplane SBP may constitute the second pixel circuit unit 820 of the display unit DP.

A third semiconductor insulating layer SINS3 may be located on the second single crystal semiconductor substrate 210. The third semiconductor insulating layer SINS3 may include silicon carbonitride (SiCN) and/or a silicon oxide (SiOₓ)-based inorganic film, but is not limited thereto.

A fourth semiconductor insulating layer SINS4 may be located on the third semiconductor insulating layer SINS3. The fourth semiconductor insulating layer SINS4 may be formed as a silicon oxide (SiOₓ)-based inorganic film, but is not limited thereto.

Each of the plurality of contact electrodes CTE may be connected to any one of the gate electrode GE, the source region SA, and the drain region DA of each of the second transistors PTR2 through a hole penetrating the third semiconductor insulating layer SINS3 and the fourth semiconductor insulating layer SINS4. The plurality of contact electrodes CTE may include (Cu), aluminum (Al), tungsten (W), molybdenum (Mo), chromium (Cr), gold (Au), titanium (Ti), nickel (Ni), and/or neodymium (Nd), and/or an alloy including two or one of them.

The pixel circuit backplane EBP may include third to seventh interlayer insulating layers INS3, INS4, INS5, INS6, and INS7 and a plurality of connection conductive layers RMT. The connection conductive layer RMT may include wires electrically connected to the plurality of second transistors PTR2 formed in the second single crystal semiconductor substrate 210. The pixel circuit backplane EBP may include the driving voltage lines VSL and VDL located in the display unit DP.

The third interlayer insulating layer INS3 may be located on the plurality of contact electrodes CTE and the semiconductor insulating layers SINS3 and SINS4. The fourth interlayer insulating layer INS4 may be located on the third interlayer insulating layer INS3. The fifth interlayer insulating layer INS5, the sixth interlayer insulating layer INS6, and the seventh interlayer insulating layer INS7 may be located sequentially on the fourth interlayer insulating layer INS4. The plurality of connection conductive layers RMT may be located between the third to seventh interlayer insulating layers INS3 to INS7. Each of the third to seventh interlayer insulating layers INS3 to INS7 may include silicon carbonitride (SiCN) and/or a silicon oxide (SiOx)-based inorganic film, but is not limited thereto. Although it is illustrated in the drawings that each of the third to seventh interlayer insulating layers INS3 to INS7 is formed as a single layer, the present disclosure is not limited thereto. Each of the third to seventh interlayer insulating layers INS3 to INS7 may have a structure in which one or more layers are stacked on top of each other, and may be located between the plurality of first to eighth conductive layers ML1 to ML8 to be described later.

The connection conductive layer RMT may have a structure similar to the plurality of conductive layers ML1 to ML8 and the vias VA1 to VA8 of the first driving circuit layer 120. The connection conductive layer RMT may include at least one conductive layer and vias located between the conductive layers, and may constitute wires located in the display unit DP, such as the driving voltage lines VSL and VDL. For example, the connection conductive layers RMT located in the display area DAA may be electrically connected to the second transistor PTR2 to constitute the pixel circuit. The connection conductive layers RMT may serve as connection wires that connect the second transistor PTR2 to other circuit elements.

The connection wiring layer CLL may be located on the bottom surface of the second single crystal semiconductor substrate 210. The connection wiring layer CLL may include an interlayer insulating layer RINS and the plurality of connection wires RML1 and RML2.

The interlayer insulating layer RINS may be located on the bottom surface of the second single crystal semiconductor substrate 210. The interlayer insulating layer RINS may be formed as a silicon carbon nitride (SiCN) and/or silicon oxide (SiOₓ)-based inorganic film, but is not limited thereto. In the drawing, the interlayer insulating layer RINS is illustrated as a single layer, but is not limited thereto and may have a structure in which one or more layers are stacked on top of each other, and they may be located between the connection wires RML1 and RML2.

The connection wires RML1 and RML2 may form the routing wires RM1 and RM2 together with the conductive vias RVA1 and RVA2. The connection wires RML1 and RML2 may include one or more conductive layers, and one or more vias connecting them to each other. The connection and structure of the connection wires RML1 and RML2 may be the same as described above for the conductive layers ML1 to ML8 and the vias VA1 to VA8. The connection wire RML may be electrically connected to the second pixel circuit unit 820 or the circuit board 300 through the conductive vias RVA1 and RVA2 located in the through holes TSV1 and TSV2 of the second single crystal semiconductor substrate 210, and may electrically connect each of them to the first driving circuit layer 120 of the first driver DRP1.

The first conductive via RVA1 of the first routing wire RM1 may be located in the first through hole TSV1. The first through hole TSV1 may penetrate the second single crystal semiconductor substrate 210, the semiconductor insulating layers SINS3 and SINS4, and the interlayer insulating layers INS3, INS4, and INS5. The first conductive via RVA1 of the first routing wire RM1 may be located in the first through hole TSV1 from the bottom surface of the sixth interlayer insulating layer INS6 to the bottom surface of the second single crystal semiconductor substrate 210, and may be connected to a first connection wire RML1. The first conductive via RVA1 may be connected to the second transistor PTR2 through the connection conductive layer RMT of the pixel circuit backplane EBP, and may be connected to the first pixel circuit unit 810 of the first driver DRP1 through the first connection wire RML1. The first connection wire RML1 may be a wire illustrated on the rear surface of the display unit DP in FIG. 20.

The second conductive via RVA2 of the second routing wire RM2 may be located in the second through hole TSV2. The second through hole TSV2 may penetrate the second single crystal semiconductor substrate 210, the semiconductor insulating layers SINS3 and SINS4, and the interlayer insulating layers INS3, INS4, and INS5. The second conductive via RVA2 of the second routing wire RM2 may be located in the second through hole TSV2 from the bottom surface of the sixth interlayer insulating layer INS6 to the bottom surface of the second single crystal semiconductor substrate 210, and may be connected to a second connection wire RML2. The second conductive via RVA2 may be connected to a write signal terminal GTD of the pixel circuit backplane EBP, and may be connected to the signal terminal STD of the first driver DRP1 through the second connection wire RML2.

In the display device, the circuit units provided in the first driver DRP1 may be formed by a high-cost micro semiconductor process, and thus may be formed with a high integration density on the first single crystal semiconductor substrate 110 having a small area. The manufacturing process of the first driver DRP1 may have a high yield per unit wafer substrate, and a circuit element (e.g., the first transistor) may have a small size, resulting in reduced power consumption. In addition, by dividedly arranging the elements constituting the pixel circuit for light emission of the light emitting element in the first driver DRP1 and the display unit DP, an excessive increase in the integration density of the first single crystal semiconductor substrate 110 may be prevented. Further, the driving voltage lines VSL and VDL to which a voltage for driving the light emitting elements is applied may be located in the display unit DP without passing through the first driver DRP1, and a voltage drop may be effectively prevented by eliminating an unnecessary current path.

The display layer 230 may be located on the second single crystal semiconductor substrate 210 and the pixel circuit backplane EBP. The display layer 230 may include the display element layer EML, the encapsulation layer TFE, the adhesive layer ADL, the optical layer OPL, and the cover layer DCL. The display layer 230 may include light emitting elements electrically connected to the first driver DRP1 and emit light.

The display element layer EML may be located on the pixel circuit backplane EBP. The display element layer EML may include the reflective electrode layer RL, eighth and ninth interlayer insulating layers INS8 and INS9, the electrode via VAP, light emitting elements, the pixel defining film PDL, and the plurality of trenches TRC. The light emitting elements may include the first electrode AND, the light emitting stack IL, and the second electrode CAT.

The reflective electrode layer RL may be located on the seventh interlayer insulating layer INS7. The reflective electrode layer RL may include at least one reflective electrode RL1, RL2, RL3, and RL4. For example, the reflective electrode layer RL may include first to fourth reflective electrodes RL1, RL2, RL3, and RL4.

Each of the first reflective electrodes RL1 may be located on the seventh interlayer insulating layer INS7 and may be connected to a via penetrating the seventh interlayer insulating layer INS7. The first reflective electrodes RL1 may include copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the first reflective electrodes RL1 may contain titanium nitride (TiN).

Each of the second reflective electrodes RL2 may be located on the first reflective electrode RL1. The second reflective electrodes RL2 may include copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the second reflective electrodes RL2 may include aluminum (Al).

Each of the third reflective electrodes RL3 may be located on the second reflective electrode RL2. The third reflective electrodes RL3 may include copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the third reflective electrodes RL3 may contain titanium nitride (TiN).

Each of the fourth reflective electrodes RL4 may be located on the third reflective electrode RL3. The fourth reflective electrodes RL4 may include copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the fourth reflective electrodes RL4 may include titanium (Ti).

In one or more embodiments, because the second reflective electrode RL2 is an electrode that substantially reflects light from the light emitting elements, the thickness of the second reflective electrode RL2 may be greater than the thickness of each of the first reflective electrode RL1, the third reflective electrode RL3, and the fourth reflective electrode RL4. For example, in one or more embodiments, the thickness of each of the first reflective electrode RL1, the third reflective electrode RL3, and the fourth reflective electrode RL4 may be approximately 100 Å, and the thickness of the second reflective electrode RL2 may be approximately 850 Å. However, in one or more embodiments, as shown in FIG. 23, the thickness of the fourth reflective electrode RL4 may be greater than the thickness of each of the first reflective electrode RL1, the third reflective electrode RL3, and the second reflective electrode RL2.

The eighth interlayer insulating layer INS8 may be located on the seventh interlayer insulating layer INS7. The eighth interlayer insulating layer INS8 may be located between the reflective electrode layers RL adjacent to each other. The eighth interlayer insulating layer INS8 may be located on the reflective electrode layer RL in the first sub-pixel SP1. The eighth interlayer insulating layer INS8 may be formed as a silicon oxide (SiOₓ)-based inorganic film, but is not limited thereto.

The ninth interlayer insulating layer INS9 may be located on the eighth interlayer insulating layer INS8 and the reflective electrode layer RL. The ninth interlayer insulating layer INS9 may be formed as a silicon oxide (SiOₓ)-based inorganic film, but is not limited thereto.

In at least one of the first sub-pixel SP1, the second sub-pixel SP2, or the third sub-pixel SP3, the eighth interlayer insulating layer INS8 and the ninth interlayer insulating layer INS9 may not be located under the first electrode AND in consideration of the resonance distance of the light emitted from the light emitting elements LE.

For example, the first electrode AND of the third sub-pixel SP3 may be directly located on the fourth reflective electrode RL4, and the first electrode AND of the third sub-pixel SP3 may not overlap the eighth interlayer insulating layer INS8 and the ninth interlayer insulating layer INS9. The first electrode AND of the second sub-pixel SP2 may be located on the ninth interlayer insulating layer INS9, and the ninth interlayer insulating layer INS9 may be directly located on the fourth reflective electrode RL4. That is, the first electrode AND of the second sub-pixel SP2 may not overlap the eighth interlayer insulating layer INS8. The first electrode AND of the first sub-pixel SP1 may be located on the ninth interlayer insulating layer INS9, and may overlap the eighth interlayer insulating layer INS8.

In one or more embodiments, the distance between the first electrode AND and the reflective electrode layer RL may be different in the first sub-pixel SP1, the second sub-pixel SP2, and the third sub-pixel SP3. In order to adjust the distance from the reflective electrode layer RL to the second electrode CAT according to the main wavelength of the light emitted from each of the first sub-pixel SP1, the second sub-pixel SP2, and the third sub-pixel SP3, the presence or absence of the eighth interlayer insulating layer INS8 and the ninth interlayer insulating layer INS9 may be set in each of the first sub-pixel SP1, the second sub-pixel SP2, and the third sub-pixel SP3. For example, the distance between the first electrode AND and the reflective electrode layer RL in the first sub-pixel SP1 may be greater than the distance between the first electrode AND and the reflective electrode layer RL in the second sub-pixel SP2 and the distance between the first electrode AND and the reflective electrode layer RL in the third sub-pixel SP3, and the distance between the first electrode AND and the reflective electrode layer RL in the second sub-pixel SP2 may be greater than the distance between the first electrode AND and the reflective electrode layer RL in the third sub-pixel SP3. However, the present disclosure is not limited thereto. The distance between the first electrode AND and the reflective electrode layer RL in each of the sub-pixels SP1, SP2, and SP3 may be variously modified and designed.

In addition, although the eighth interlayer insulating layer INS8 and the ninth interlayer insulating layer INS9 are illustrated in the drawing, a tenth interlayer insulating layer may be further located under the first electrode AND of the sub-pixel SP. In this case, the ninth interlayer insulating layer INS9 and the tenth interlayer insulating layer may be located under the first electrode AND of the second sub-pixel SP2, and the eighth interlayer insulating layer INS8, the ninth interlayer insulating layer INS9, and the tenth interlayer insulating layer may be located under the first electrode AND of the first sub-pixel SP1.

Each of the electrode vias VAP may be connected to the fourth reflective electrode RL4 exposed through the eighth interlayer insulating layer INS8 and/or the ninth interlayer insulating layer INS9 in the first sub-pixel SP1 and the second sub-pixel SP2. The electrode vias VAP may include copper (Cu), aluminum (Al), tungsten (W), molybdenum (Mo), chromium (Cr), gold (Au), titanium (Ti), nickel (Ni), and/or neodymium (Nd), and/or an alloy including two or more of them. The thickness of the electrode via VAP in the second sub-pixel SP2 may be less than the thickness of the electrode via VAP in the first sub-pixel SP1.

The first electrode AND of each of the light emitting elements may be located on the ninth interlayer insulating layer INS9 or the reflective electrode layer RL and may be connected to the electrode via VAP. The first electrode AND of each of the light emitting elements LE may be connected to the second transistor PTR2 through the electrode via VAP, the first to fourth reflective electrodes RL1 to RL4, the connection conductive layer RMT, and the contact electrode CTE. The first electrode AND of each of the light-emitting elements may include copper (Cu), aluminum (Al), tungsten (W), molybdenum (Mo), chromium (Cr), gold (Au), titanium (Ti), nickel (Ni), and/or neodymium (Nd), and/or an alloy including two or more of them. For example, the first electrode AND of each of the light-emitting elements may be titanium nitride (TiN).

The pixel defining film PDL may be located on a part of the first electrode AND of each of the light-emitting elements. The pixel defining film PDL may cover the edge of the first electrode AND of each of the light-emitting elements. The pixel defining film PDL may serve to partition the first emission areas EA1, the second emission areas EA2, and the third emission areas EA3.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be located on the edge of the first electrode AND of each of the light emitting elements LE, the second pixel defining film PDL2 may be located on the first pixel defining film PDL1, and the third pixel defining film PDL3 may be located on the second pixel defining film PDL2. The first pixel defining film PDL1, the second pixel defining film PDL2, and the third pixel defining film PDL3 may be formed as silicon oxide (SiOₓ)-based inorganic films, but are not limited thereto. The first pixel defining film PDL1, the second pixel defining film PDL2, and the third pixel defining film PDL3 may each have a thickness of about 500 Å.

When the first pixel defining film PDL1, the second pixel defining film PDL2, and the third pixel defining film PDL3 are formed as one pixel defining film, the height of the one pixel defining film increases, so that a first inorganic encapsulation layer TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

In order to reduce or prevent the likelihood of the first inorganic encapsulation layer TFE1 being cut off due to the step coverage, the first pixel defining film PDL1, the second pixel defining film PDL2, and the third pixel defining film PDL3 may have a cross-sectional structure having a stepped portion. For example, the width of the first pixel defining film PDL1 may be greater than the width of the second pixel defining film PDL2 and the width of the third pixel defining film PDL3, and the width of the second pixel defining film PDL2 may be greater than the width of the third pixel defining film PDL3. The width of the first pixel defining film PDL1 refers to the horizontal length of the first pixel defining film PDL1 defined in the first direction DR1 and the second direction DR2.

Each of the plurality of trenches TRC may penetrate the first pixel defining film PDL1, the second pixel defining film PDL2, and the third pixel defining film PDL3. In each of the plurality of trenches TRC, a part of the eighth interlayer insulating layer INS8 may be dug and the ninth interlayer insulating layer INS9 may be penetrated.

At least one trench TRC may be located between the neighboring sub-pixels SP1, SP2, and SP3. It is illustrated in the drawing that two trenches TRC are located between the adjacent sub-pixels SP1, SP2, and SP3, but the present disclosure is not limited thereto.

The light emitting stack IL may include a plurality of stacks. It is illustrated in the drawing that the light emitting stack IL has a three-tandem structure including a first light emitting stack IL1, a second light emitting stack IL2, and a third light emitting stack IL3, but the present disclosure is not limited thereto. For example, the light emitting stack IL may have a two-tandem structure including two light emitting stacks.

In the three-tandem structure, the light emitting stack IL may have a tandem structure including the plurality of light emitting stacks IL1, IL2, and IL3 that emit different lights. For example, the light emitting stack IL may include the first light emitting stack IL1 that emits light of the first color, the second light emitting stack IL2 that emits light of the third color, and the third light emitting stack IL3 that emits light of the second color. The first light emitting stack IL1, the second light emitting stack IL2, and the third light emitting stack IL3 may be sequentially stacked.

The first light emitting stack IL1 may have a structure in which a first hole transport layer, a first organic light emitting layer that emits light of the first color, and a first electron transport layer are sequentially stacked. The second light emitting stack IL2 may have a structure in which a second hole transport layer, a second organic light emitting layer that emits light of the third color, and a second electron transport layer are sequentially stacked. The third light emitting stack IL3 may have a structure in which a third hole transport layer, a third organic light emitting layer that emits light of the second color, and a third electron transport layer are sequentially stacked.

A first charge generation layer for supplying charges to the second light emitting stack IL2 and supplying electrons to the first light emitting stack IL1 may be located between the first light emitting stack IL1 and the second light emitting stack IL2. The first charge generation layer may include an N-type charge generation layer that supplies electrons to the first light emitting stack IL1 and a P-type charge generation layer that supplies holes to the second light emitting stack IL2. The N-type charge generation layer may include a dopant of a metal material.

A first charge generation layer for supplying charges to the third light emitting stack IL3 and supplying electrons to the second light emitting stack IL2 may be located between the second light emitting stack IL2, and the third light emitting stack IL3. The second charge generation layer may include an N-type charge generation layer that supplies electrons to the second light emitting stack IL2 and a P-type charge generation layer that supplies holes to the third light emitting stack IL3.

The first light emitting stack IL1 may be located on the first electrodes AND and the pixel defining film PDL, and may be located on the bottom surface of each trench TRC. Due to the trench TRC, the first light emitting stack IL1 may be cut off between the neighboring sub-pixels SP1, SP2, and SP3. The second light emitting stack IL2 may be located on the first light emitting stack IL1. Due to the trench TRC, the second light emitting stack IL2 may be cut off between the neighboring sub-pixels SP1, SP2, and SP3. A cavity or an empty space may be located between the first light emitting stack IL1 and the second light emitting stack IL2. The third light emitting stack IL3 may be located on the second light emitting stack IL2. The third light emitting stack IL3 is not cut off by the trench TRC and may be located to cover the second light emitting stack IL2 in each of the trenches TRC. That is, in the three-tandem structure, each of the plurality of trenches TRC may be a structure for cutting off the first to second light emitting stacks IL1 and IL2, the first charge generation layer, and the second charge generation layer of the display element layer EML between the neighboring sub-pixels SP1, SP2, and SP3. In addition, in the two-tandem structure, each of the plurality of trenches TRC may be a structure for cutting off the charge generation layer and a lower light emitting stack located between the lower light emitting stack and an upper light emitting stack.

In order to stably cut off the first and second light emitting stacks IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the first to third light emitting stacks IL1, IL2, and IL3 of the display element layer EML between the neighboring sub-pixels SP1, SP2, and SP3, another structure may exist instead of the trench TRC. For example, instead of the trench TRC, a reverse tapered partition wall may be located on the pixel defining film PDL.

The number of the light emitting stacks IL1, IL2, and IL3 that emit different lights is not limited to that shown in the drawing. For example, the light emitting stack IL may include two light emitting stacks. In this case, one of the two light emitting stacks may be substantially the same as the first light emitting stack IL1, and the other may include a second hole transport layer, a second organic light emitting layer, a third organic light emitting layer, and a second electron transport layer. In this case, a charge generation layer for supplying electrons to one light emitting stack and supplying charges to the other light emitting stack may be located between the two light emitting stacks.

In addition, it is illustrated in the drawing that the first to third light emitting stacks IL1, IL2, and IL3 are all located in the first emission area EA1, the second emission area EA2, and the third emission area EA3, but the present disclosure is not limited thereto. For example, the first light emitting stack IL1 may be located in the first emission area EA1, and may not be located in the second emission area EA2 and the third emission area EA3. Furthermore, the second light emitting stack IL2 may be located in the second emission area EA2 and may not be located in the first emission area EA1 and the third emission area EA3. Further, the third light emitting stack IL3 may be located in the third emission area EA3 and may not be located in the first emission area EA1 and the second emission area EA2. In this case, first to third color filters CF1, CF2, and CF3 of the optical layer OPL may be omitted.

The second electrode CAT may be located on the third light emitting stack IL3. The second electrode CAT may be located on the third light emitting stack IL3 in each of the plurality of trenches TRC. The second electrode CAT may include a transparent conductive material (TCO) such as ITO and/or IZO that can transmit light or a semi-transmissive conductive material such as magnesium (Mg), silver (Ag), or an alloy of Mg and Ag. When the second electrode CAT includes a semi-transmissive conductive material, the light output efficiency may be improved in each of the first to third sub-pixels SP1, SP2, and SP3 due to a micro-cavity effect. The second electrode CAT may be electrically connected to the first driving voltage line VSL in the common electrode contact area CTA of the non-display area NDA.

The encapsulation layer TFE may be located on the display element layer EML. The encapsulation layer TFE may include at least one inorganic encapsulation layer TFE1 and TFE3 to reduce or prevent oxygen or moisture from permeating into the display element layer EML. In addition, the encapsulation layer TFE may include at least one organic film to protect the display element layer EML from foreign substances such as dust. For example, the encapsulation layer TFE may include the first inorganic encapsulation layer TFE1, an organic encapsulation layer TFE2, and a second inorganic encapsulation layer TFE3.

The first inorganic encapsulation layer TFE1 may be located on the second electrode CAT, the organic encapsulation layer TFE2 may be located on the first inorganic encapsulation layer TFE1, and the second inorganic encapsulation layer TFE3 may be located on the organic encapsulation layer TFE2. The first inorganic encapsulation layer TFE1 and the second inorganic encapsulation layer TFE3 may be formed as multiple films in which one or more inorganic films of silicon nitride (SiNₓ), silicon oxynitride (SiOₓN_{y}), silicon oxide (SiOₓ), titanium oxide (TiOₓ), and/or aluminum oxide (AlOₓ) layers are alternately stacked. The organic encapsulation layer TFE2 may be a monomer. Alternatively, the organic encapsulation layer TFE2 may be an organic film such as acryl resin, epoxy resin, phenolic resin, polyamide resin, polyimide resin, and/or the like.

The adhesive layer ADL may be located on the encapsulation layer TFE. The adhesive layer ADL may be a layer for bonding the encapsulation layer TFE to a layer located thereon. The adhesive layer ADL may be a double-sided adhesive member. In addition, the adhesive layer ADL may be a transparent adhesive member such as a transparent adhesive or a transparent adhesive resin.

The optical layer OPL may include the color filter layer CFL, the plurality of first lenses LNS1, and a filling layer FIL. The color filter layer CFL may include the first to third color filters CF1, CF2, and CF3. The first to third color filters CF1, CF2, and CF3 may be located on the adhesive layer ADL.

The first color filter CF1 may overlap the first emission area EA1. The first color filter CF1 may transmit light of the first color, i.e., light of a red wavelength band. The red wavelength band may be about 600 nm to about 750 nm. The first color filter CF1 may transmit light of the first color among light emitted from the first emission area EA1.

The second color filter CF2 may overlap the second emission area EA2. The second color filter CF2 may transmit light of the second color, i.e., light of a green wavelength band. The green wavelength band may be about 480 nm to about 560 nm. The second color filter CF2 may transmit light of the second color among light emitted from the second emission area EA2.

The third color filter CF3 may overlap the third emission area EA3. The third color filter CF3 may transmit light of the third color, i.e., light of a blue wavelength band. The blue wavelength band may be about 370 nm to about 460 nm. The third color filter CF3 may transmit light of the third color among light emitted from the third emission area EA3.

The plurality of first lenses LNS1 may be located on the first color filter CF1, the second color filter CF2, and the third color filter CF3, respectively. Each of the plurality of first lenses LNS1 may be a structure for increasing the proportion of light directed to the front of the display device. Each of the plurality of first lenses LNS1 may have a cross-sectional shape that is convex in an upward direction.

The filling layer FIL may be located on the plurality of first lenses LNS1. The filling layer FIL may have a selected refractive index such that light travels in the third direction DR3 at an interface between the filling layer FIL and the plurality of first lenses LNS1. Further, the filling layer FIL may be a planarization layer. The filling layer FIL may be an organic film such as acrylic resin, epoxy resin, phenolic resin, polyamide resin, and/or polyimide resin.

The cover layer DCL may be located on the filling layer FIL. The cover layer DCL may be a glass substrate and/or a polymer resin. When the cover layer DCL is a glass substrate, it may be attached onto the filling layer FIL. In this case, the filling layer FIL may serve to bond the cover layer DCL. When the cover layer DCL is a glass substrate, it may serve as an encapsulation substrate. When the cover layer DCL is a polymer resin, it may be directly applied onto the filling layer FIL.

In one or more embodiments, the display unit DP may further include a polarizing plate located on the cover layer DCL. The polarizing plate may be located on one surface of the cover layer DCL. The polarizing plate may be a structure for reducing or preventing visibility degradation caused by reflection of external light. The polarizing plate may include a linear polarizing plate and a phase retardation film. For example, the phase retardation film may be a λ/4 plate (quarter-wave plate), but is not limited thereto. However, when visibility degradation caused by reflection of external light is sufficiently overcome by the first to third color filters CF1, CF2, and CF3, the polarizing plate may be omitted.

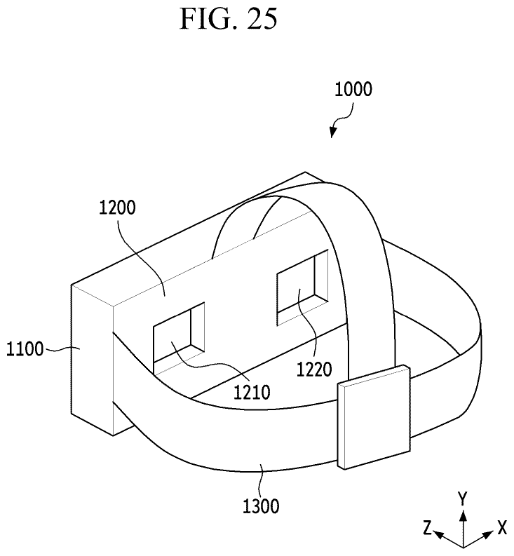

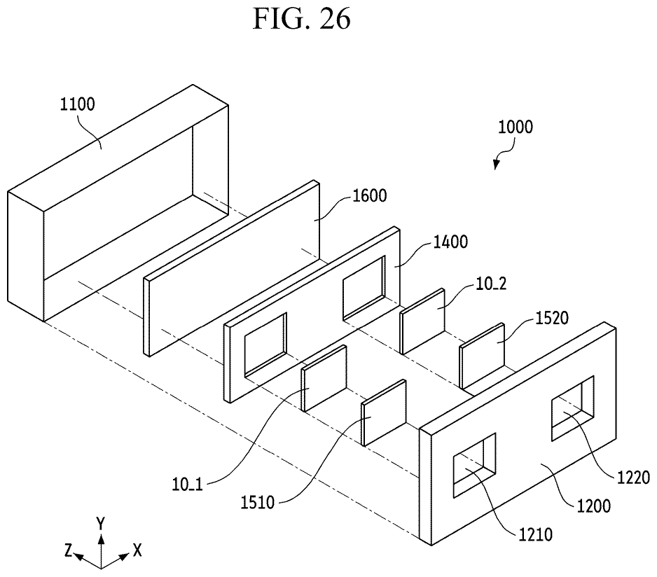

FIG. 25 is a perspective view illustrating a head mounted display according to one or more embodiments of the present disclosure. FIG. 26 is an exploded perspective view illustrating an example of the head mounted display of FIG. 25.

Referring to FIGS. 25 and 26, a head mounted display 1000 according to one or more embodiments of the present disclosure includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Since each of the first display device 10_1 and the second display device 10_2 is substantially the same as the display device 10 described above, the description of the first display device 10_1 and the second display device 10_2 will be omitted.

The first optical member 1510 may be located between the first display device 10_1 and the first eyepiece 1210. The second optical member 1520 may be located between the second display device 10_2 and the second eyepiece 1220. Each of the first optical member 1510 and the second optical member 1520 may include at least one convex lens.

The middle frame 1400 may be located between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be located between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is located to cover one open surface of the display device housing 1100. The housing cover 1200 may include the first eyepiece 1210 at which the user's left eye is located and the second eyepiece 1220 at which the user's right eye is located. FIGS. 25 and 26 illustrate that the first eyepiece 1210 and the second eyepiece 1220 are located separately, but the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

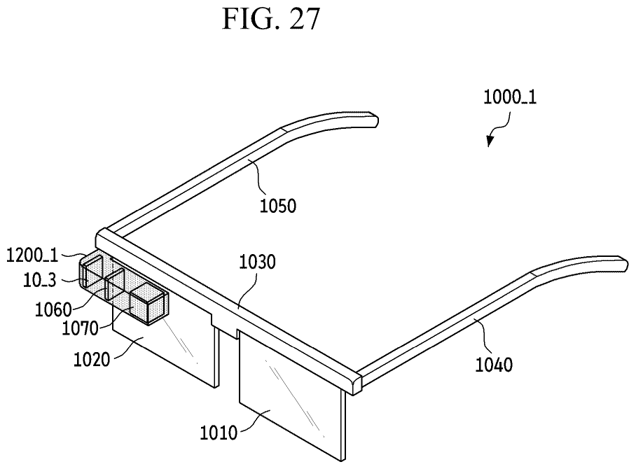

The head mounted band 1300 serves to secure the display device housing 1100 to the user's head such that the first eyepiece 1210 and the second eyepiece 1220 of the housing cover 1200 remain located on the user's left and right eyes, respectively. When the display device housing 1200 is implemented to be lightweight and compact, the head mounted display 1000 may be provided with, as shown in FIG. 27, an eyeglass frame instead of the head mounted band 1300.

FIG. 27 is a perspective view illustrating a head mounted display according to one or more embodiments of the present disclosure.

Referring to FIG. 27, a head mounted display 1000_1 according to one or more embodiments may be an eyeglasses-type display device in which a display device housing 1200_1 is implemented in a lightweight and compact manner. The head mounted display 1000_1 according to one or more embodiments may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 27 illustrates that the display device housing 1200_1 is located at the right end of the support frame 1030, but the embodiment of the present specification is not limited thereto. For example, the display device housing 1200_1 may be located at the left end of the support frame 1030, and in this case, the image of the display device 10_3 may be provided to the user's left eye. Alternatively, the display device housing 1200_1 may be located at both the left and right ends of the support frame 1030, and in this case, the user may view the image displayed on the display device 10_3 through both the left and right eyes.

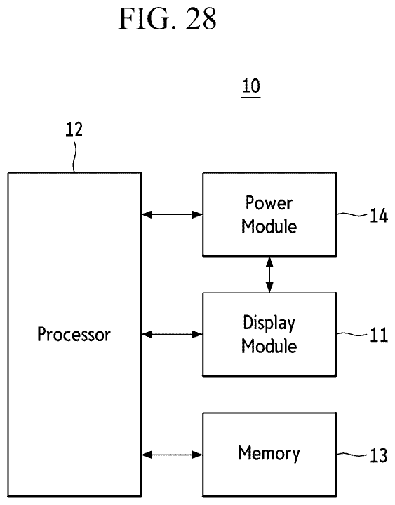

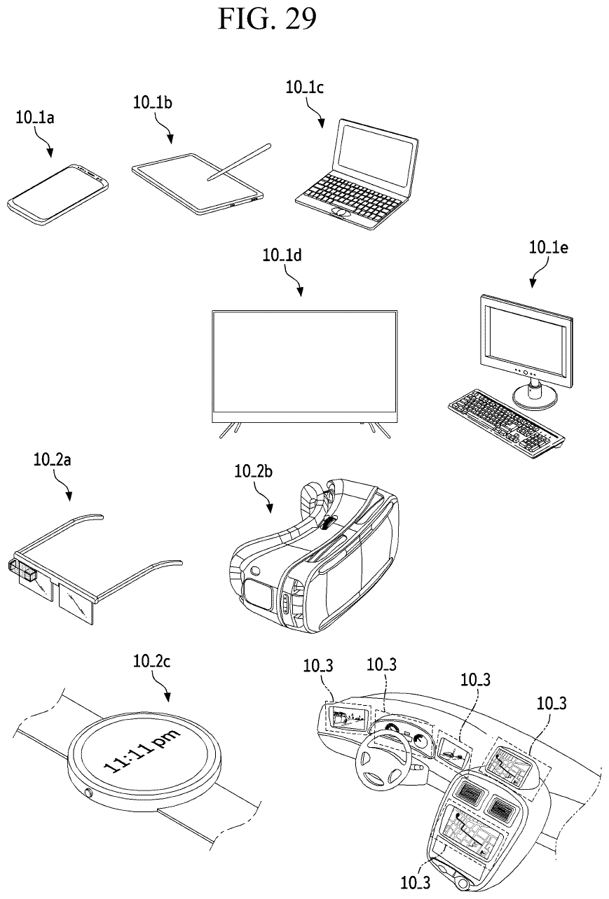

FIG. 28 is a block diagram of an electronic device according to one or more embodiments of the present disclosure. FIG. 29 is schematic diagrams of electronic devices according to various embodiments of the present disclosure.

Referring to FIG. 28, an electronic device 10 according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 15 may store data information required for the operation of the processor 12 or the display module 11. When the processor 12 executes an application stored in the memory 15, an image data signal and/or an input control signal is transmitted to the display module 11, and the display module 11 may process the received signal and output image information through a display screen.

The power module 14 may include a power supply module such as a power adapter or a battery device. The power module 14 may include a power conversion module. The power conversion module may convert the power supplied by the power supply module to generate a power required for the operation of the electronic device 10.

At least one of the components of the electronic device 10 described above may be included in the display device according to the embodiments described above. Further, some of individual modules functionally included in one module may be included in the display device and some others may be provided separately from the display device. For example, the display device may include the display module 11, whereas the processor 12, the memory 13 and the power module 14 may be provided in the form of other devices in the electronic device, other than the display device.

Referring to FIG. 29, various electronic devices to which display devices according to embodiments of the present disclosure are applied may include an electronic device for displaying images, such as a smartphone 10_1a, a tablet PC 10_1b, a laptop 10_1c, a TV 10_1d, and a desk monitor 10_1e. In addition, various electronic devices to which the display devices according to the embodiments of the present disclosure are applied may include a wearable electronic device including a display module such as smart glasses 10_2a, a head mounted display 10_2b, and a smart watch 10_2c, a vehicle electronic device 10_3 including a display module such as a center fascia, and a dashboard of an automobile, a center information display (CID) placed on the dashboard, a room mirror display, and the like.

Although embodiments of the disclosure have been described above with reference to the accompanying drawings, it will be understood by those having ordinary skill in the technical field to which the disclosure belongs that the disclosure may be practiced in other specific forms without altering the technical idea or essential features of the disclosure. It should therefore be understood that the embodiments described above are exemplary in all respects and are not intended to be limiting.

What is claimed is:

1. A display device comprising:
a first substrate;
a second substrate located on one side of the first substrate and coupled with the first substrate;
a first pixel group located on a first surface of the first substrate; and
a second pixel group located on a first surface of the second substrate,
wherein the first substrate and the second substrate comprise different materials.

2. The display device of claim 1, wherein the first substrate is a single crystal semiconductor substrate, and
wherein the second substrate is a glass substrate or a plastic substrate.

3. The display device of claim 1, wherein the first substrate comprises:
a first sub-substrate comprising a first pixel circuit unit; and
a second sub-substrate located on the first sub-substrate and comprising a second pixel circuit unit connected to the first pixel circuit unit, and a plurality of light emitting elements connected to the first pixel circuit unit.

4. The display device of claim 3, wherein an area of the first sub-substrate is smaller than an area of the second sub-substrate.

5. The display device of claim 1, wherein the number per unit area of first pixels in the first pixel group is different from the number per unit area of second pixels in the second pixel group.

6. The display device of claim 3, further comprising:
a first driving circuit unit configured to drive the first pixel group; and
a second driving circuit unit configured to drive the second pixel group,
wherein the first driving circuit unit is located on the first surface of the first sub-substrate and connected to the first pixel group via a plurality of through holes.

7. The display device of claim 1, further comprising:
a first driving circuit unit configured to drive the first pixel group; and
a second driving circuit unit configured to drive the second pixel group,
wherein the second substrate comprises a main region and a sub-region extending from one side of the main region, the sub-region comprising a flexible material, and
wherein the second driving circuit unit is located in the sub-region and connected to the second pixel group.

8. The display device of claim 7, wherein the sub-region comprises a bending portion, and
wherein the second driving circuit unit is located on one side of the bending portion and located on a second surface of the second substrate.

9. The display device of claim 1, wherein the second substrate comprises a plurality of second substrates, and
wherein the plurality of second substrates is connected to the first substrate and surrounds the first substrate.

10. The display device of claim 9, wherein the second substrate comprises a main region and a sub-region extending from one side of the main region, the sub-region comprising a flexible material, and
wherein positions of the sub-regions on the plurality of second substrates are all the same.

11. The display device of claim 1, wherein a size of an emission area defined by each of a plurality of pixels in the first pixel group is different from a size of an emission area defined by each of a plurality of pixels in the second pixel group.

12. The display device of claim 1, further comprising:
a boundary portion located between the first substrate and the second substrate;
a first lens group located on the first substrate;
a second lens group located on the second substrate; and
a third lens group located at the boundary portion.

13. The display device of claim 12, wherein a direction in which light is refracted by the first lens group is different from a direction in which light is refracted by the third lens group.

14. The display device of claim 12, wherein a direction in which light is refracted by the second lens group is different from a direction in which light is refracted by the third lens group.

15. The display device of claim 12, wherein a refraction angle of light by the first lens group is different from a refraction angle of light by the second lens group.

16. The display device of claim 15, wherein the refraction angle of light by the first lens group is less than the refraction angle of light by the second lens group, and
wherein a refraction angle of light by the third lens group is less than the refraction angle of light by the first lens group.

17. An electronic device comprising:
a processor configured to provide an image signal;
a display module configured to receive the image signal from the processor and configured to display an image; and
a power module configured to supply power to the display module,
wherein the display module comprises:
a first substrate;
a second substrate located on one side of the first substrate and coupled with the first substrate;
a first pixel group located on a first surface of the first substrate;
and a second pixel group located on a first surface of the second substrate,
wherein the first substrate and the second substrate comprise different materials.

18. The electronic device of claim 17, the first substrate is a single crystal semiconductor substrate, and
wherein the second substrate is a glass substrate or a plastic substrate.

19. The electronic device of claim 17, wherein the first substrate comprises:
a first sub-substrate comprising a first pixel circuit unit; and
a second sub-substrate located on the first sub-substrate and comprising a second pixel circuit unit connected to the first pixel circuit unit, and a plurality of light emitting elements connected to the first pixel circuit unit.

20. The electronic device of claim 17, wherein the display module further comprises:
a boundary portion located between the first substrate and the second substrate;
a first lens group located on the first substrate;
a second lens group located on the second substrate; and
a third lens group located at the boundary portion.
